(19) United States
(12) Patent Application Publication
(10) Pub. No.: US 2012/0280303 A1
(43) Pub. Date: Nov. 8, 2012

(54) NON-VOLATILE SEMICONDUCTOR MEMORY DEVICE AND METHOD OF MANUFACTURING THE SAME

(75) Inventors: Masahiro KIYOTOSHI, Mie (JP); Kiwamu Sakuma, Kanagawa (JP); Haruka Kusai, Kanagawa (JP)

(73) Assignee: KABUSHIKI KAISHA TOSHIBA, Tokyo (JP)

(21) Appl. No.: 13/366,845

(22) Filed: Feb. 6, 2012

(30) Foreign Application Priority Data
May 2, 2011 (JP) 2011-102816

(51) Int. Cl. H01L 29/788; H01L 21/336

(52) U.S. Cl. 257/316; 438/264; 257/E21.422; 257/E29.3

(57) ABSTRACT

According to one embodiment, a first trench extending in a first direction is formed in a stacked structure in which a plurality of spacer films and a plurality of channel semiconductor films are alternately stacked. A first space is formed by forming a recess in the channel semiconductor films from the first trench. A tunnel dielectric film is formed in the first space, and the first space is further filled with a floating gate electrode film. Second trenches that divide the stacked structure at predetermined interval in the first direction are formed so as to divide the floating gate electrode film between memory cells adjacent to each other in the first direction but not to divide the channel semiconductor films.

### CROSS-REFERENCE TO RELATED APPLICATIONS

This application is based upon and claims the benefit of priority from Japanese Patent Application No. 2011-102816, filed on May 2, 2011; the entire contents of which are incorporated herein by reference.

### FIELD

Embodiments described herein relate generally to a non-volatile semiconductor memory device and a method of manufacturing the same.

### BACKGROUND

In the field of NAND flash memories, as a result of the rapid advance in downsizing of device size for a reduction in cost through enhancement of bit density, cell size has nearly reached a physical limit of operation or processing. Therefore, a stacked nonvolatile memory formed by three-dimensionally stacking memory cells attracts attention as means for attaining higher bit density. As the stacked nonvolatile memory, stacked nonvolatile memories of a metal-oxide-nitride-oxide-semiconductor (MONOS) type and a floating gate type in which a floating gate is formed in a doughnut shape are proposed.

However, in the stacked nonvolatile memory of the MONOS type, reliability of a memory operation is low. It is difficult to realize a multi-value operation such as multi-level-cell (MLC: information for two bits is stored in one memory cell) and triple-level-cell (TLC: information for three bits is stored in one memory cell) universally used in a floating gate structure.

In the stacked nonvolatile memory in which the floating gate electrode film is formed in a doughnut shape, a projection area of a memory cell (corresponding to a cell area in a planar floating gate type structure) is large. The structure and the process of the stacked nonvolatile memory are substantially different from those of a nonvolatile memory of a planar floating gate type widely used in the past. This hinders replacement of the nonvolatile memory of the planar floating gate type in the past with the stacked nonvolatile memory.

### BRIEF DESCRIPTION OF THE DRAWINGS

FIG. 1 is a perspective view schematically illustrating an example of the structure of a non-volatile semiconductor memory device according to a first embodiment;

FIGS. 2A to 2C are cross-sectional views schematically illustrating an example of the structure of the non-volatile semiconductor memory device according to the first embodiment;

FIGS. 3A to 12C are cross-sectional views schematically illustrating an example of a process of a method of manufacturing the non-volatile semiconductor memory device according to the first embodiment;

FIG. 13 is a perspective view schematically illustrating another example of the structure of the non-volatile semiconductor memory device according to the first embodiment;

FIG. 14 is a perspective view schematically illustrating an example of the structure of a non-volatile semiconductor memory device according to a second embodiment;

FIGS. 15A to 15C are cross-sectional views schematically illustrating an example of the structure of the non-volatile semiconductor memory device according to the second embodiment;

FIGS. 16A to 19C are cross-sectional views schematically illustrating an example of a process of a method of manufacturing the non-volatile semiconductor memory device according to the second embodiment;

FIGS. 20A to 23C are cross-sectional views schematically illustrating an example of a process of a method of manufacturing a non-volatile semiconductor memory device according to a third embodiment;

FIGS. 24A to 26C are cross-sectional views schematically illustrating an example of a process of a method of manufacturing a non-volatile semiconductor memory device according to a fourth embodiment;

FIGS. 27A and 27B are diagrams illustrating an example of a cross-sectional structure in the process of manufacturing the non-volatile semiconductor memory device according to the second embodiment;

FIGS. 28A to 34C are cross-sectional views schematically illustrating an example of a process of a method of manufacturing a non-volatile semiconductor memory device according to a fifth embodiment;

FIGS. 35A to 41C are cross-sectional views schematically illustrating an example of a process of a method of manufacturing a non-volatile semiconductor memory device according to a sixth embodiment;

FIGS. 42A and 42B are perspective views schematically illustrating an example of the structure of a non-volatile semiconductor memory device according to an embodiment; and

FIG. 43 is a diagram illustrating a scaling scenario of a non-volatile semiconductor memory device according to an embodiment.

### DETAILED DESCRIPTION

In general, according to one embodiment, first, a stacked structure including a plurality of layers in which a spacer film and a channel semiconductor film are alternately stacked is formed above a substrate. Next, a first trench extending in a first direction is formed in the stacked structure, and a first space is formed by forming a recess in the channel semiconductor films from the first trench in a second direction perpendicular to the first direction. Thereafter, a tunnel dielectric film is formed on the channel semiconductor films in the first space, and the first space in which the tunnel dielectric film is formed is filled with a floating gate electrode film. Then, second trenches that divide the stacked structure at predetermined interval in the first direction are formed so as to divide the floating gate electrode film between memory cells adjacent to each other in the first direction but so as not to divide the channel semiconductor films. The stacked structure is divided at predetermined interval in the second direction so that the channel semiconductor films are divided between memory cells adjacent to each other in the second direction.

Hereinafter, a non-volatile semiconductor memory device and a method of manufacturing the same according to exemplary embodiments will be described in detail with reference to the accompanying drawings. The present invention is not limited to the following embodiments. Cross-sectional views of a non-volatile semiconductor memory device used in the following embodiments are schematic views, and a relation between a thickness and a width of layers, a radio between thicknesses of layers, and the like may differ from actual ones. In addition, film thicknesses used in the following description are examples, and the present invention is not limited thereto.

### First Embodiment

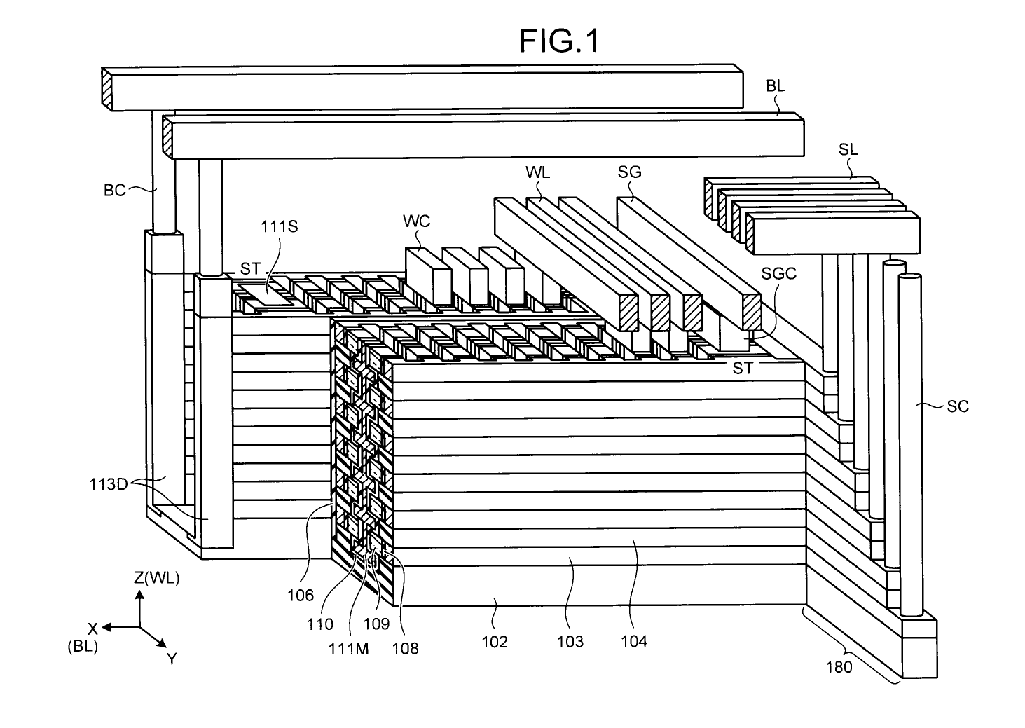

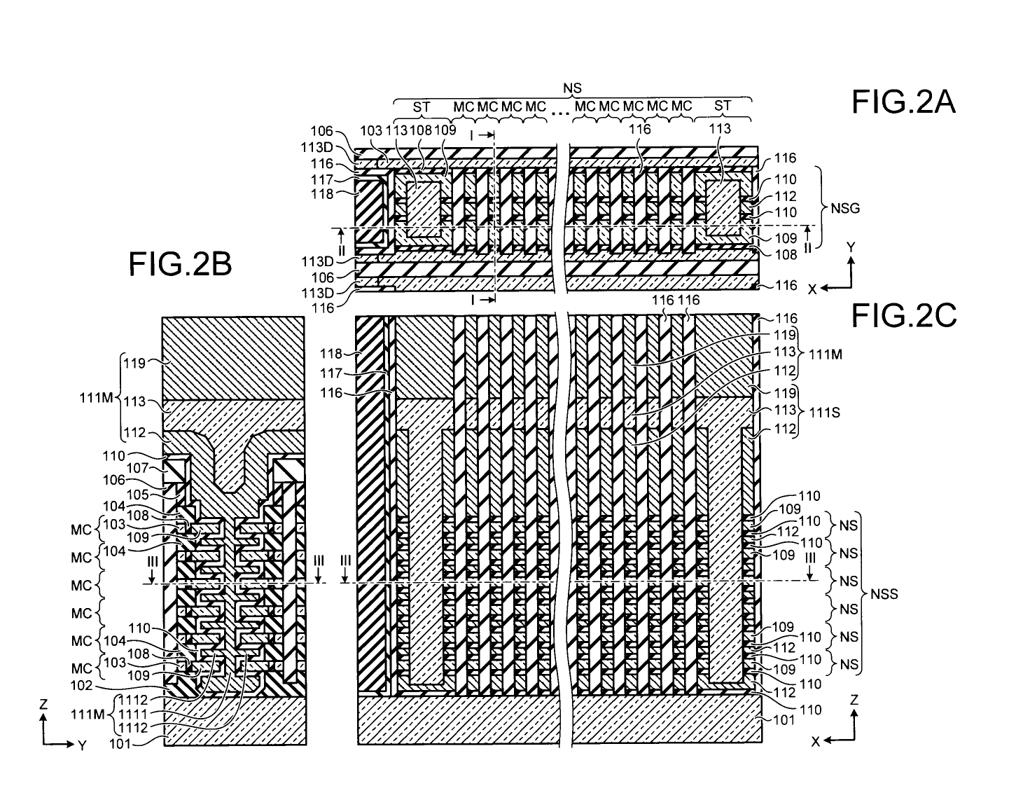

FIG. 1 is a perspective view schematically illustrating an example of the structure of a non-volatile semiconductor memory device according to a first embodiment. In FIG. 1, an appropriate structure is taken and illustrated in order to help with understanding with a structure of the non-volatile semiconductor memory device, and an inter-level dielectric (ILD) film is not illustrated. FIGS. 2A to 2C are cross-sectional views schematically illustrating an example of the structure of the non-volatile semiconductor memory device according to the first embodiment. FIG. 2A is a cross-sectional view viewed in a direction parallel to a substrate surface at a forming position of a floating gate electrode film. FIG. 2B is a cross-sectional view taken along line I-I of FIG. 2A. FIG. 2C is a cross-sectional view taken along line II-II of FIG. 2A. FIG. 2A corresponds to a cross-sectional view taken along line III-III of FIGS. 2B and 2C. Further, in the following description, a direction in which a bit line extends in the substrate surface is defined as an X direction, a direction in which a word line perpendicular to the bit line extends in the substrate surface is defined as a Y direction, and a direction vertical to the substrate surface is defined as a Z direction.

The non-volatile semiconductor memory device has a structure in which a plurality of NAND string stacks NSS are arranged, in the X direction and the Y direction, on an ILD film 102 formed on a semiconductor substrate 101. The NAND string stack NSS has a structure in which a plurality of NAND strings NS are stacked, in the Z direction, through spacer films 104. The NAND string NS extends in the X direction and includes a plurality of memory cell transistors (hereinafter, referred to as “memory cell”) MC formed in series in the X direction on one main surface of a channel semiconductor film 103, which is an active area of a sheet shape parallel to a substrate surface, in the Y direction. Here, a NAND string group NSG includes a pair of NAND string stacks NSS arranged so that forming surfaces of memory cells MC can face each other. The NAND string groups NSG are arranged on the semiconductor substrate 101 in a matrix shape. The adjacent NAND string groups NSG are isolated by a gap-fill dielectric film 106.

The memory cell MC has a floating gate type structure. The memory cell MC includes a floating gate electrode film 109 extending in the Y direction and a pair of control gate electrode films 111M which are provided on both sides of the floating gate electrode film 109 in the Z direction. The floating gate electrode film 109 is formed above the channel semiconductor film 103 through the tunnel dielectric film 108. The control gate electrode film 111M is arranged to face the floating gate electrode film 109 through an inter-poly dielectric (IPD) film 110.

The control gate electrode film 111M includes a common connecting section 1111 extending in the Z direction and electrode forming sections 1112 that protrude from the common connecting section 1111 in the Y direction and are provided on both sides of the floating gate electrode film 109 in the Z direction through the IPD film 110. Thus, the control gate electrode film 111M is shared between the memory cells MC arranged in the Z direction. The electrode forming section 1112 is provided, above a side surface of the spacer film 104 in the Y direction through the IPD film 110, between the floating gate electrode films 109 arranged in the Z direction. Further, the control gate electrode film 111M is shared between one memory cell row arranged in the Z direction and another memory cell row faced by the forming surface of the memory cell MC of one memory cell row. In this example, the control gate electrode film 111M is configured with a film formed such that a conductive film 112 filled in a space between a pair of memory cell rows having the memory cells MC whose forming surfaces face each other, a conductive film 113 provided on the conductive film 112, and a silicide film 119 are stacked.

A sidewall film 116 made of an insulating material is filled in a space between the memory cells MC (the floating gate electrode film 109 and the control gate electrode film 111M) adjacent to each other in the X direction, and between the memory cell MC and the selection transistor ST.

The selection transistors ST, which control a connection with a source region or a drain region, are provided on both ends of the NAND string NS. The selection transistor ST includes a selection gate electrode film 1115 arranged, through the tunnel dielectric film 108, above one main surface of the channel semiconductor film 103 in the Y direction at both end portions of the memory cells MC arranged in the X direction. The selection gate electrode film 111S has a structure in which in a stacking structure of the IPD film 110, the conductive film 112, and the floating gate electrode film 109, the conductive film 113 is filled in a through hole extending in the Z direction by partially removing the IPD film 110, and the silicide film 119 is formed on the conductive film 113. That is, the selection gate electrode film 111S is configured with the floating gate electrode film 109, the conductive films 112 and 113, and the silicide film 119, and the selection gate electrode film 111S is shared between the selection transistors ST arranged in the Z direction. Further, similarly to the control gate electrode film 111M, the selection gate electrode film 111S is also shared between selection transistor ST rows, facing each other, within the NAND string group NSG. A source side selection transistor ST is arranged on one end of the NAND string NS in the X direction, and a drain side selection transistor ST is arranged on the other end of the NAND string NS.

The source region is provided on one end of the channel semiconductor film 103 in the X direction at the side at which the source side selection transistor ST is arranged, and the channel semiconductor films 103 that configure the NAND strings NS of the same height adjacent to each other in the Y direction are connected to each other. A lead-out section 180 connected to the cell array outside is provided. The lead-out section 180 has a step-like shape so that the channel semiconductor film 103 positioned in a lower layer can be exposed. A source line contact SC is provided on each step-difference portion and is connected to a source line SL, which extends in the X direction, above the cell array.

The drain region is provided on one end of the channel semiconductor film 103 in the X direction at the side at which the drain side selection transistor ST is arranged. In the drain region, end portions of the NAND strings NS adjacent to each other in the Z direction are connected to each other by a drain region connection contact 113D of a pillar shape extending in the Z direction. For example, the drain region connection contact 113D is made of the same material as the conductive film 113. Further, the drain region connection contact 113D is connected to a bit line BL extending in the X direction, through a bit line contact BC, above the drain region connection contact 113D.

The drain region connection contact 113D is provided for each NAND string stack NSS, and the drain region connection contacts 113D, adjacent to each other in the Y direction, within the NAND string group NSG are isolated from each other by a dielectric film. In this example, the dielectric film is configured with the sidewall film 116 formed along an inner wall of an isolation trench for isolating the drain region connection contacts 113D from each other, a dielectric film 117 covering the inner surface of the isolation trench, and a gap-fill dielectric film 118 filled in the isolation trench.

The control gate electrode film 111M, which connects the memory cells MC arranged in the Z direction to each other, is connected to a word line WL extending in the Y direction, through a word line contact WC, above the control gate electrode film 111M. Similarly, the selection gate electrode film 1115, which connects the selection transistors ST arranged in the Z direction, is connected to a selection gate line SG extending in the Y direction, through a selection gate line contact SGC, above the selection gate electrode film 1115.

For example, the semiconductor substrate 101 and the channel semiconductor film 103 may be made of a material selected from among Si, Ge, SiGe, SiSn, PbS, GaAs, InP, GaP, GaN, ZnSe, InGaAsP, and the like. The channel semiconductor film 103 may be made of a single crystalline semiconductor or a poly crystalline semiconductor.

For example, a silicon oxide film may be used as the tunnel dielectric film 108. An amorphous silicon film, a polysilicon film, or the like into which impurities such as phosphorous (P) or boron (B) is doped may be used as the floating gate electrode film 109. Further, a silicon oxide film or the like may be used as the IPD film 110. Further, as the control gate electrode film 111M and the selection gate electrode film 111S, a metal film made of W, TaN, WN, TiAlN, TiN, WSi, CoSi, NiSi, PrSi, NiPtSi, PtSi, Pt, Ru, or the like, RuO₂, a B-doped polysilicon film, a P-doped polysilicon film, a silicide film, or a stacked film thereof can be used.

The example of the drawings illustrates the structure in which 6 channel semiconductor films 103 are stacked in the Z direction. However, the number of stacked channel semiconductor films 103 is not limited thereto, and an arbitrary number of channel semiconductor films 103 may be stacked. Further, the number of memory cells MC formed on one channel semiconductor film 103 in the X direction may be an arbitrary number. The memory cell MC arranged at a position adjacent to the selection transistor ST may deteriorate due to influence of strong electric field caused by the selection transistor ST, and so may function as not an actual memory cell but a dummy memory cell.

In the non-volatile semiconductor memory device having the above configuration, an arbitrary memory cell MC is selected such that a position on a plane parallel to the semiconductor substrate 101 is selected through the word line WL and the bit line BL and a stacked layer is selected through the source line SL. The memory cell MC does not individually include an impurity diffusion region that functions as the source/drain region. By forming a depletion layer in the channel semiconductor film 103 between the adjacent control gate electrode films 111M through fringing field formed by applying a voltage to each control gate electrode films 111M, formed is a channel connected to the entire channel semiconductor film 103.

Each memory cell transistor MC is an inversion type transistor or a depletion type transistor having no source/drain structure. Typically, in memory cells MC having no source/drain structure, a region where high-concentration electrons exist is not present in a channel, even though Vₚₐₛₛ is applied to a non-selected cell, a program disturb or read disturb hardly occurs.

A writing operation on an arbitrary floating gate electrode film 109 is performed such that electrons are injected from the source region into the selected memory cell MC through the depletion layer formed in the channel semiconductor film 103. An erasing operation is performed such that electrons are collectively pulled out from the floating gate electrode films 109 of all memory cells MC on the channel semiconductor film 103 by increasing electric potential of the channel semiconductor film 103. A method of selecting an arbitrary memory cell MC is not limited to the above example since a plurality of methods or wiring structures are present.

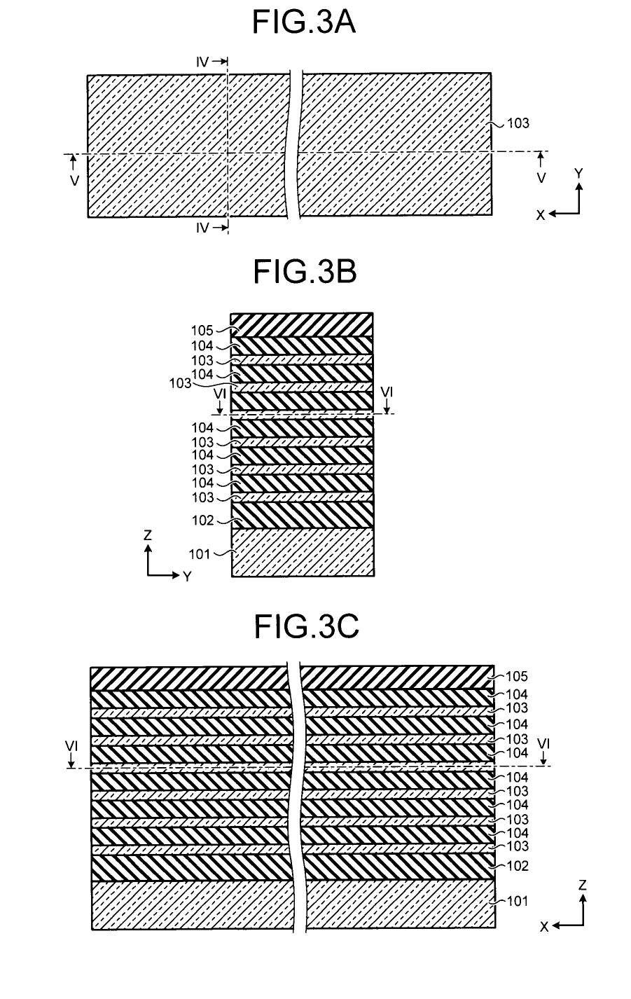

Next, a description will be made in connection with a method of manufacturing the non-volatile semiconductor memory device having the above structure. FIGS. 3A to 12C are cross-sectional views schematically illustrating an example of a process of a method of manufacturing the non-volatile semiconductor memory device according to the first embodiment. In these drawings, FIGS. 3A to 12A are cross-sectional views viewed in a direction parallel to the substrate surface at the forming position of the floating gate electrode film, FIGS. 3B to 12B are cross-sectional views taken along line IV-IV of FIGS. 3A to 12A, and FIGS. 3C to 12C are cross-sectional views taken along line V-V of FIGS. 3A to 12A. FIGS. 3A to 12A correspond to cross-sectional views taken along line VI-VI of FIGS. 3B to 12B and FIGS. 3C and 12C.

In the following, described is an example of manufacturing a non-volatile semiconductor memory device having a structure in which 6 layers each of which includes the channel semiconductor film 103 and the spacer film 104 are stacked at a pitch of 60 nm in parallel to the semiconductor substrate 101, a half pitch in the Y direction is 62 nm, and a half pitch in the X direction is 25 nm. As a result, bit density equal to a NAND type flash memory of a two-dimensional structure (a planar floating gate type structure) in which a half pitch is 16.1 nm can be achieved. Further, a method of forming a peripheral circuit and a lead-out portion is the same as in a method of forming a typical non-volatile semiconductor memory device or a typical stacked non-volatile semiconductor memory device, and thus a detailed description thereof will not be provided.

First, as illustrated in FIGS. 3A to 3C, a peripheral circuit (not illustrated) of a non-volatile semiconductor memory device is formed on a semiconductor substrate 101. Next, an ILD film 102 is formed on the entire surface of the semiconductor substrate 101. For example, a silicon oxide film having a thickness of 100 nm may be used as the ILD film 102.

Thereafter, a plurality of layers (here, 6 layers) in which a channel semiconductor film 103 and a spacer film 104 are alternately stacked are formed on the ILD film 102. For example, an amorphous silicon film having a thickness of 20 nm may be used as the channel semiconductor film 103, and a silicon oxide film having a thickness of 40 nm may be used as the spacer film 104.

Further, a hard mask film 105 is formed on the spacer film 104 of the top layer. For example, a silicon nitride film having a thickness of 50 nm may be used as the hard mask film 105. Further, the hard mask film 105 may be formed using SiCN, SiBN, alumina, titania, zirconia, or the like besides the silicon nitride film. However, the hard mask film 105 is preferably formed using a material that is easily recess-etched.

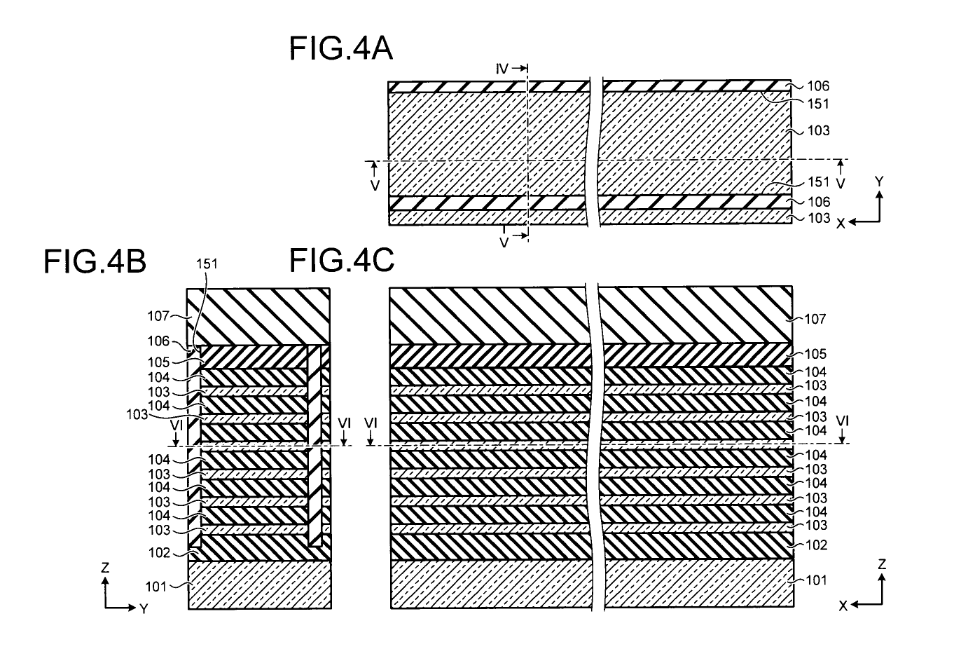

Next, as illustrated in FIGS. 4A to 4C, by collectively processing the stacked films, which includes the hard mask film 105, the spacer film 104, and the channel semiconductor film 103, using a lithography technique and a reactive ion etching technique (hereinafter, referred to as “RIE technique”), a trench 151, which extends in the X direction to expose a part of the ILD film 102, is formed at a predetermined pitch in the Y direction. For example, the width of the trench 151 may be set to 25 nm, and the pitch may be set to 248 nm. The trench 151 corresponds to one which divides the stacked film in association with an area for forming the NAND string group NSG, and isolates the channel semiconductor films 103 of the memory cells MC, adjacent to each other, in the NAND string groups NSG adjacent to each other in the Y direction, in FIG. 1 and FIGS. 2A to 2C.

Thereafter, a gap-fill dielectric film 106 is formed in the trench 151. The top surface of the gap-fill dielectric film 106 is planarized using a chemical mechanical polishing (CMP) technique, and so the top surface of the hard mask film 105 is exposed in a region other than the position at which the trench 151 is formed. For example, a silicon oxide film formed by a chemical vapor deposition (CVD) technique may be used as the gap-fill dielectric film 106. Then, a hard mask film 107 is formed over the entire surface of the semiconductor substrate 101. For example, a silicon nitride film having a thickness of 100 nm may be used as the hard mask film 107.

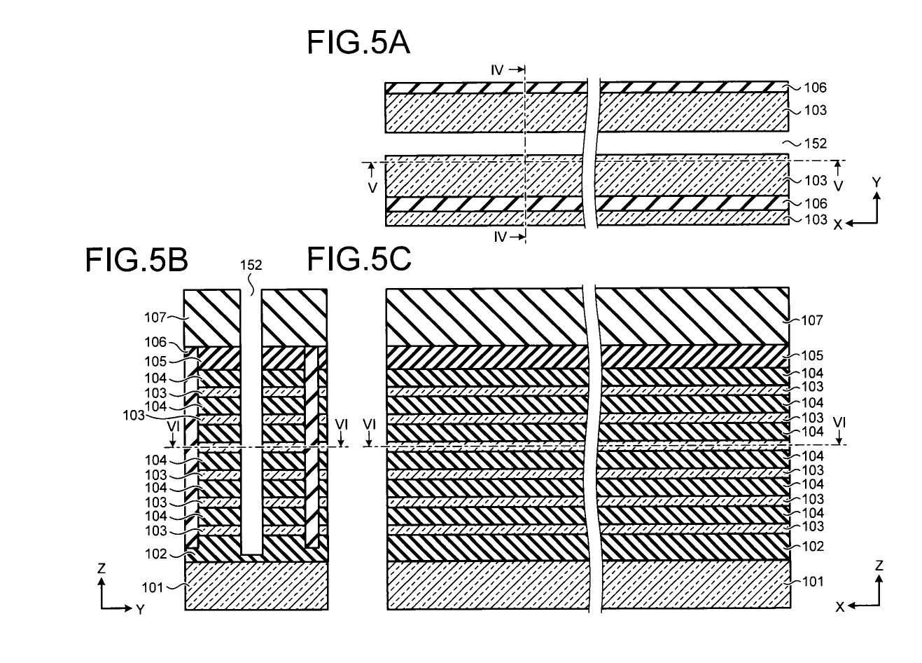

Next, as illustrated in FIGS. 5A to 5C, by collectively processing the stacked films, which includes the hard mask films 107 and 105, the spacer film 104, and the channel semiconductor film 103, using a lithography technique and an RIE technique, a trench 152, which extends in the X direction to expose a part of the ILD film 102, is formed at a predetermined pitch in the Y direction. For example, the width of the trench 152 may be set to 45 nm. The trench 152 corresponds to one which divides an area for forming the NAND string stack NSS in FIG. 1 and FIGS. 2A to 2C.

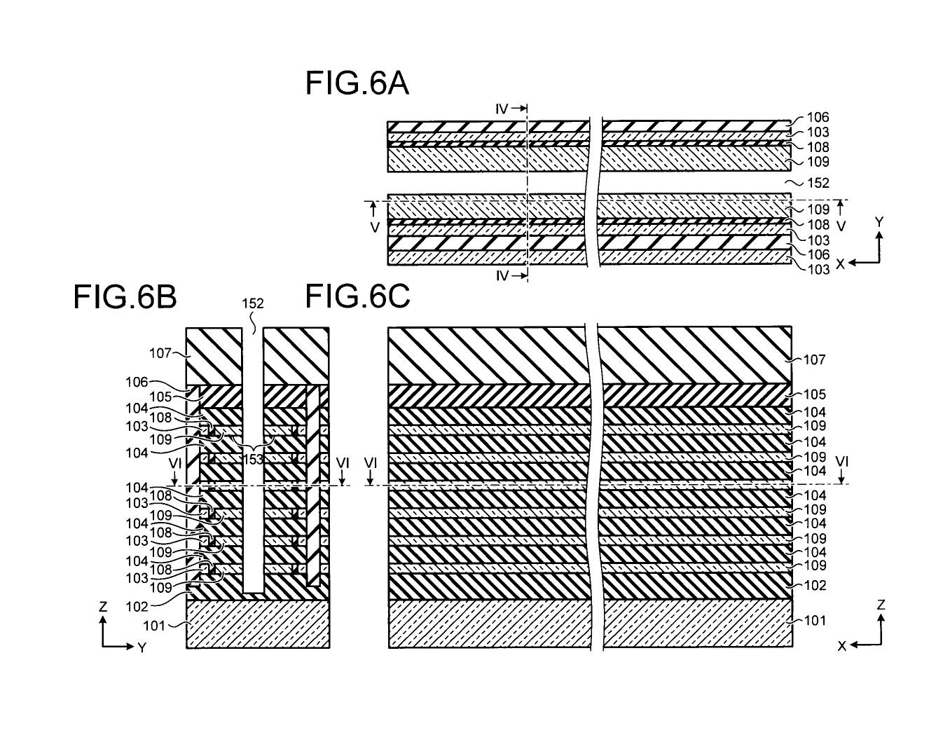

Thereafter, as illustrated in FIGS. 6A to 6C, a space 153 is formed by forming a recess in the channel semiconductor film 103 by a predetermined amount in the Y direction by using an etching technique. For example, a wet etching technique using choline, a chemical dry etching (CDE) technique, a dry etching technique using chlorine gas, or the like may be used as the etching technique. For example, the recess amount of the channel semiconductor film 103 may be set to 50 nm.

Next, a tunnel dielectric film 108 is formed on a side surface of the channel semiconductor film 103 inside the space 153. For example, the tunnel dielectric film 108 may be formed using a technique such as thermal oxidation technique and a plasma nitridation technique. For example, the thickness of the tunnel dielectric film 108 may be set to 8 nm. Then, a floating gate electrode film 109 is formed over the entire surface of the semiconductor substrate 101. For example, a P-doped amorphous silicon film having a thickness of 15 nm formed by a low pressure CVD (LPCVD) technique may be used as the floating gate electrode film 109. Thereafter, the floating gate electrode film 109 is dry-etched so that the floating gate electrode film 109 can remain only in the space 153 formed by recess-etching the channel semiconductor film 103. For example, chlorine gas may be used as etching gas.

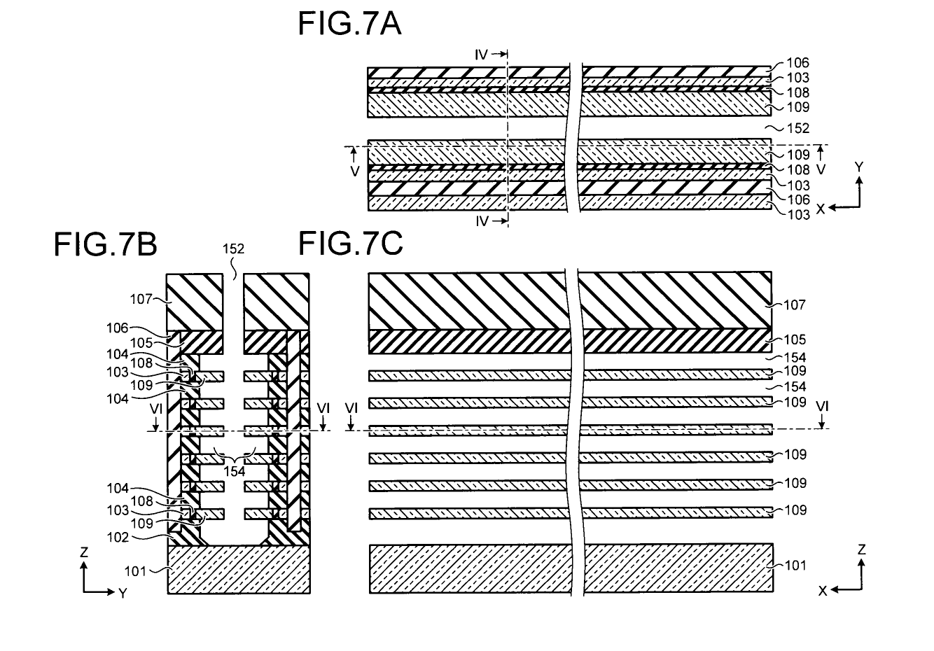

Next, as illustrated in FIGS. 7A to 7C, the spacer film 104 is isotropically etched. A recess is formed in the spacer film 104 from an end portion of the floating gate electrode film 109, which configures the side wall of the trench 152, in the Y direction by a predetermined amount. As a result, a space 154 to be filled with the control gate electrode film 111M is formed. For example, a wet etching technique or a dry etching technique using HF/NH₃ gas may be used as the isotropic etching. For example, the recess amount of the spacer film 104 may be set to 40 nm.

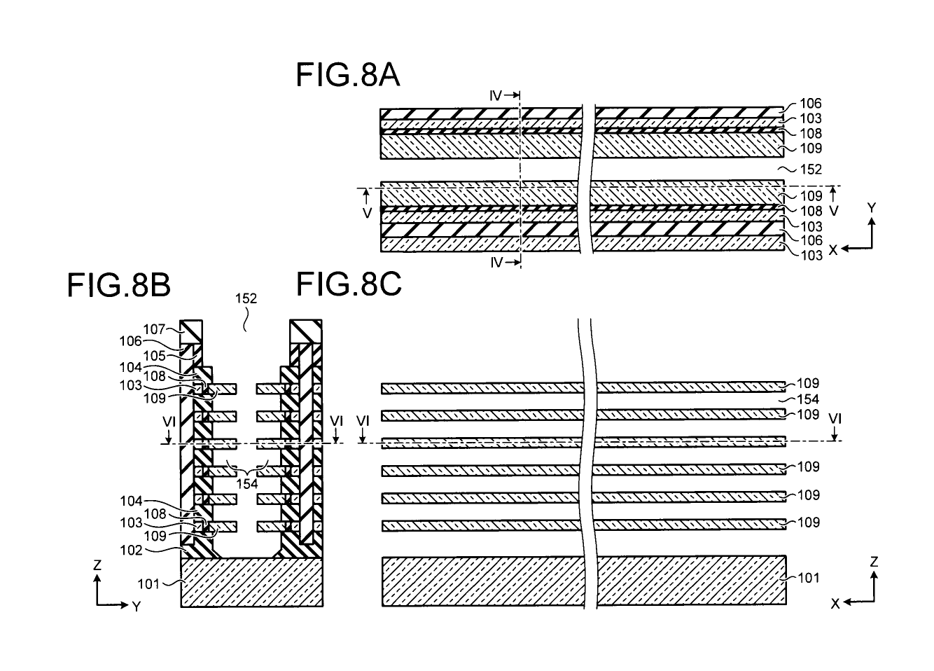

Further, as illustrated in FIGS. 8A to 8C, the hard mask films 107 and 105 are isotropically etched from an end portion of the floating gate electrode film 109 in the Y direction by a predetermined amount. For example, a wet etching technique using a hot phosphoric acid may be used as the isotropic etching technique. For example, the recess amount of the hard mask films 107 and 105 may be set to 50 nm. The hard mask films 107 and 105 are formed to cause the channel semiconductor film 103 to be protected in a self-aligning manner so as to prevent the channel semiconductor film 103 from being etched even when a trench forming mask is misaligned when an electrode pattern forming trench for isolating the memory cells MC adjacent to each other in the X direction is formed later. For this reason, the recess amount of the hard mask films 107 and 105 is set so that the hard mask films 107 and 105 can cover the recessed channel semiconductor film 103. Further, if the hard mask films 107 and 105 overlap the forming position of the floating gate electrode film 109, the floating gate electrode films 109 of the memory cells MC adjacent to each other in the X direction may be electrically connected to each other when an electrode pattern forming trench is formed later. Thus, a recess is formed in the hard mask films 107 and 105 not to cover the floating gate electrode film 109.

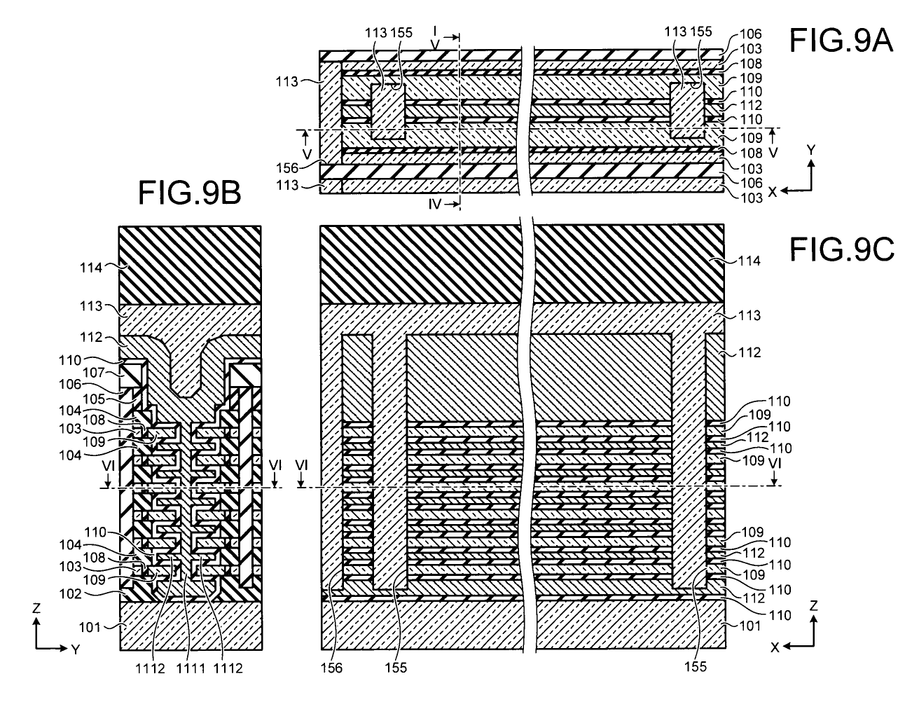

Next, as illustrated in FIGS. 9A to 9C, an IPD film 110 is formed over the entire surface of the semiconductor substrate 101. The IPD film 110 is formed to conformally cover the inner surface of the space 154. A SiN—SiO—SiN—SiO—SiN (NONON) film having a thickness of 12 nm may be used as the IPD film 110.

Subsequently, a conductive film 112 is formed over the entire surface of the semiconductor substrate 101. Here, the conductive film 112 is filled in the trench 152 and the space 154 formed in the trench 152. For example, a P-doped polysilicon film having a thickness of 50 nm may be used as the conductive film 112. The conductive film 112 functions as part of the control gate electrode film 111M and part of the selection gate electrode film 1115, and has a structure in which the electrode forming section 1112 is formed in the space 154, and the electrode forming sections 1112 of the control gate electrode films 111M, which are stacked in the Z direction through the IPD film 110, are connected to each other, between the floating gate electrode films 109, by the common connecting section 1111 extending in the Z direction.

Thereafter, a mask film (not illustrated) is formed over the semiconductor substrate 101, and a selection gate electrode film-forming trench 155 and a drain region connection contact forming trench 156 are formed by a lithography technique and an RIE technique. The selection gate electrode film-forming trench 155 is formed by collectively processing the stacked films so that the floating gate electrode films 109, the IPD films 110, and the conductive films 112 of a pair of NAND string stacks NSS, which face each other, in the forming regions of the selection transistors ST can be partially removed and so the conductive film 112 of the lowest layer can be exposed. The drain region connection contact forming trench 156 is formed by collectively processing the stacked films in part of the drain region of each NAND string stack NSS so that the conductive film 112 of the lowest layer can be exposed. Here, the drain region connection contact forming trench 156 is formed in a region between the gap-fill dielectric films 106 of the pair of NAND string stacks NSS. For example, a CVD carbon film may be used as the mask film. After the selection gate electrode film-forming trench 155 and the drain region connection contact forming trench 156 are formed, the mask film is removed.

Thereafter, a conductive film 113 is filled in the selection gate electrode film-forming trench 155 and the drain region connection contact forming trench 156. For example, a P-doped polysilicon film having a thickness of 80 nm may be used as the conductive film 113. As a result, in the forming region of the selection transistor ST, the floating gate electrode film 109 and the conductive films 112 and 113 are physically connected to each other. Subsequently, a hard mask film 114, which will be used later for processing the control gate electrode film, is formed over the semiconductor substrate 101. For example, a silicon nitride film having a thickness of 150 nm may be used as the hard mask film 114.

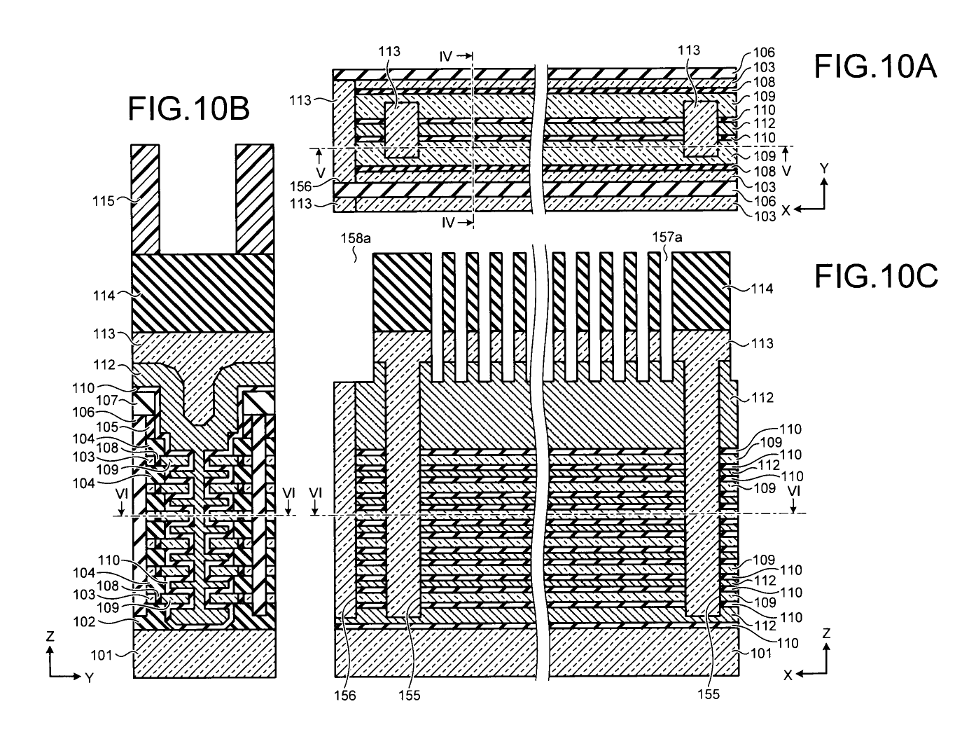

Next, as illustrated in FIGS. 10A to 10C, by processing the hard mask film 114 and the conductive films 113 and 112 by a lithography technique and an RIE technique, an electrode pattern having a predetermined half pitch in the X direction is formed in the forming region of the memory cell MC. Specifically, an electrode pattern forming trench 157a is formed, between a pair of selection transistors ST arranged in the X direction, at a half pitch of, for example, 25 nm in the X direction. Further, an isolation trench 158a, which isolates the drain region connection contacts of the pair of NAND string stacks NSS, is formed in the vicinity of the forming region of the drain side selection transistor ST.

Thereafter, the entire surface over the semiconductor substrate 101 is coated with a photoresist film. The photoresist film is patterned by a lithography technique to cover a non-processed region, so that a photoresist pattern 115 is formed. The photoresist pattern 115 may be formed to protect the channel semiconductor film 103 (the active area) of the memory cell MC as illustrated in FIGS. 10A to 100, however, precise aligning is required. However, in the first embodiment, the hard mask films 107 and 105 are formed to protect the channel semiconductor film 103 from being etched as described above with reference to FIGS. 8A to 8C. Thus, even though the photoresist pattern 115 is not precisely aligned with the channel semiconductor film 103, the channel semiconductor film 103 of the memory cell MC can be protected in a self-aligning manner.

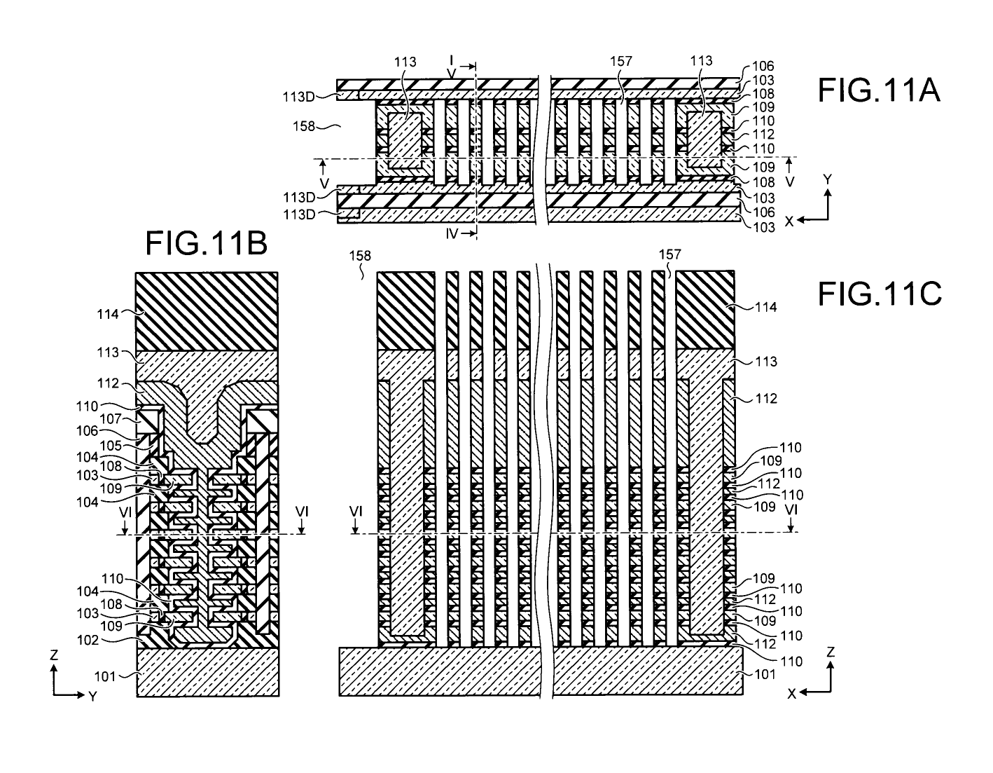

Next, as illustrated in FIGS. 11A to 11C, an electrode pattern forming trench 157 is formed by collectively processing the stacked films from the conductive film 112 to the bottom surface of the ILD film 102 using the electrode pattern previously formed in the forming region of the memory cell MC as a mask. As a result, the floating gate electrode film 109 is divided for each memory cell MC in the forming region of the memory cell MC. Further, the IPD film 110 and the conductive films 112 and 113 are divided at predetermined intervals in the X direction to extend in the Z direction. At this time, nearby the forming region of the drain side selection transistor ST, the isolation trench 158 connected to the bottom surface of the ILD film 102 is formed, the conductive film 113 filled between the pair of NAND string stacks NSS is isolated, and the drain region connection contact 113D is formed for each NAND string stack NSS. After the stacked films are collectively processed, the photoresist pattern 115 is removed.

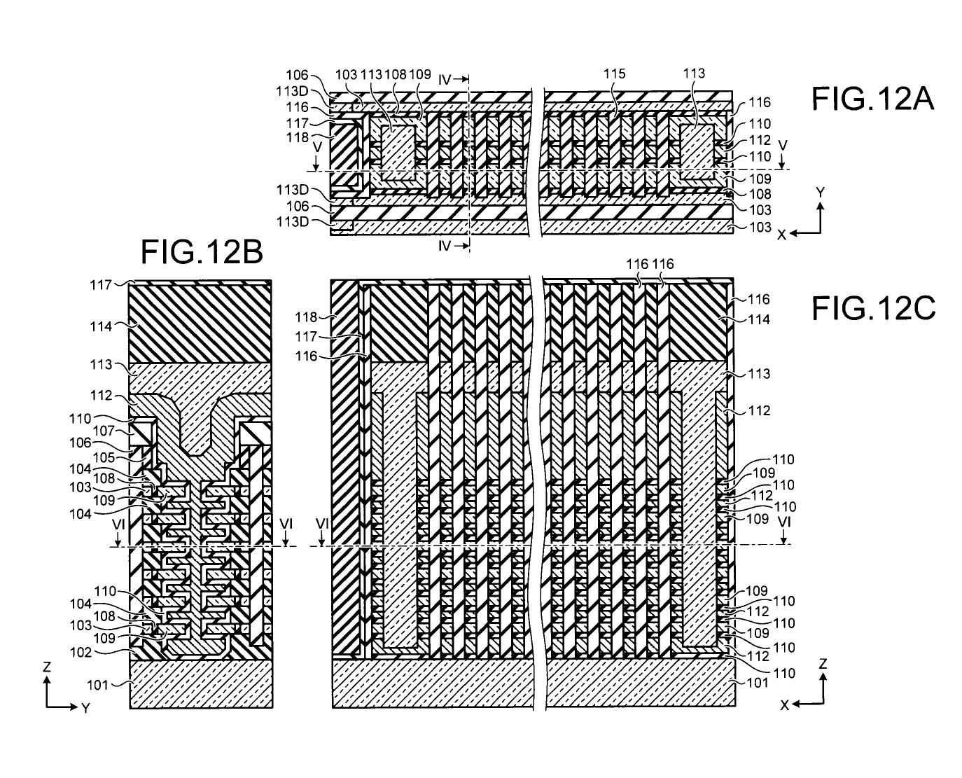

Thereafter, as illustrated in FIGS. 12A to 12C, an oxidation process is performed to oxidize the side surfaces of the floating gate electrode film 109 and the conductive films 112 and 113, so that processing damages are removed. A sidewall film 116 is formed on the side surfaces of the conductive films 112 and 113 in the X direction. For example, the oxidation process may be performed using in-situ steam generator (ISSG) oxidation, and a silicon oxide film having a thickness of 20 nm may be used as the sidewall film 116. As a result, the sidewall film 116 is also formed on the side surface of the isolation trench 158. Next, a dielectric film 117 is formed to conformally cover the entire surface over the semiconductor substrate 101. For example, a silicon nitride film having a thickness of 10 nm may be used as the dielectric film 117. Then, a gap-fill dielectric film 118 is formed in the isolation trench 158, and a planarization process is performed using a CMP technique. For example, a boron phosphorus doped silicate glass (BPSG) film having a thickness of 300 nm may be used as the gap-fill dielectric film 118. As the gap-fill dielectric film 118 is formed, spaces between the conductive films 112 and 113 and the floating gate electrode film 109 are completely filled.

Thereafter, as illustrated in FIGS. 2A to 2C, the hard mask film 114 and the dielectric film 117, which are formed above the top surface of the conductive film 113, are removed by a RIE technique. Subsequently, a silicide film 119 is formed on the conductive film 113 using a silicidation technique. For example, the silicide film 119 may be formed using CoSi₂, NiSi, PrSi₂, or the like. As a result, in the forming region of the memory cell MC, the control gate electrode film 111M is formed of the conductive films 112 and 113 and the silicide film 119. In the forming region of the selection transistor ST, the selection gate electrode film 1115 is formed of the floating gate electrode film 109, the conductive films 112 and 113, and the silicide film 119.

Then, an ILD film (not illustrated) is formed, and thereafter a contact plug and a wiring are formed. However, the contact plug and the wiring may be formed using a known technique, and thus a detailed description thereof will not be provided. Through the above process, the non-volatile semiconductor memory device according to the first embodiment is obtained.

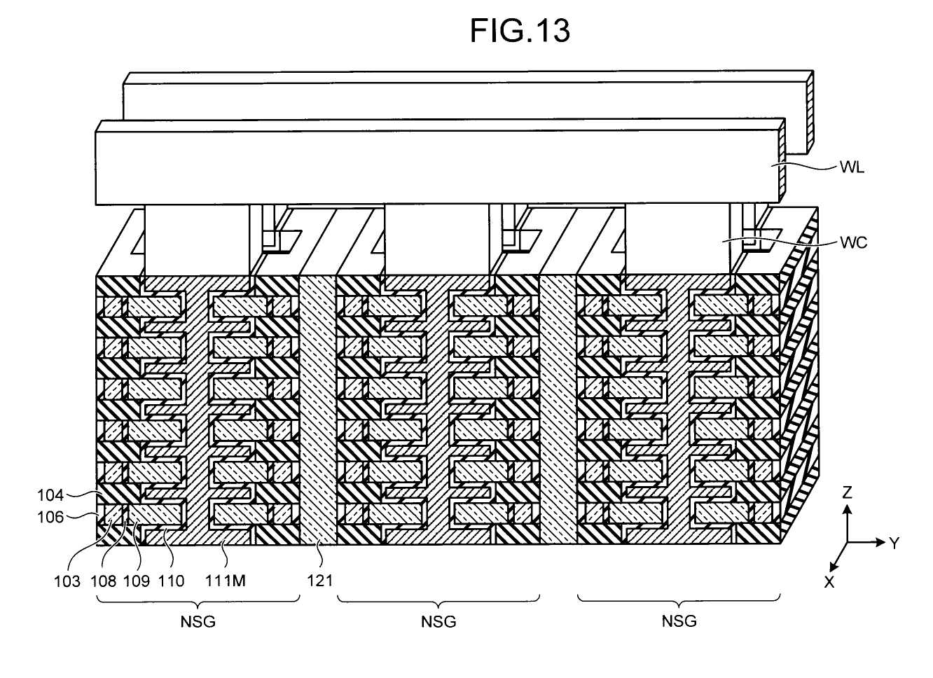

FIG. 13 is a perspective view schematically illustrating another example of a structure of the non-volatile semiconductor memory device according to the first embodiment. In FIG. 13, some of dielectric films are not illustrated. The non-volatile semiconductor memory device has the same structure as in FIG. 1, and includes a back gate electrode film 121 formed, through a gate dielectric film, on a surface opposite to the memory cell-forming surface of the channel semiconductor film 103. That is, provided is a structure in which the back gate electrode film 121 is filled between the NAND string groups NSG adjacent to each other in the Y direction through the gate dielectric film. The gap-fill dielectric film 106 illustrated in FIG. 1 and FIGS. 2A to 2C may be used as the gate dielectric film.

In the stacked non-volatile semiconductor memory device, the erasing operation tends to be more difficult than the writing operation. It is because unlike the planar floating gate type structure, it is difficult to apply an erasing voltage to a semiconductor channel through a substrate, and instead channel potential has to be raised by a voltage supplied from a source line SL. In this regard, by employing the structure illustrated in FIG. 13, the channel potential can be easily raised by an applying a high voltage to the back gate electrode film 121 at the time of erasing, so that erasing characteristics can be improved. That is, by employing the structure illustrated in FIG. 13, the memory cells MC are easily collectively erased.

In the first embodiment, a plurality of sheet shaped channel semiconductor films 103, which are parallel to the substrate surface and extend in the X direction, are stacked in the Z direction through the spacer films 104. The floating gate electrode films 109, which extend in the Y direction, are provided at predetermined intervals in the X direction on one side surfaces of the channel semiconductor films 103 in the Y direction through the tunnel dielectric film 108. Further, the control gate electrode films 111M are provided on both surfaces of the floating gate electrode film 109 in the Z direction through the IPD film 110. Further, the control gate electrode film 111M is provided to connect the memory cells MC arranged in the Z direction with each other. As a result, there are advantages of minimizing the projected area of the memory cell MC and increasing the memory density while suppressing the number of stacked layers. Further, each memory cell MC has the same structure of the planar floating gate type structure which has been widely used in the past. Thus, the conventional planar floating gate type structure can be easily replaced with the stacked non-volatile semiconductor memory device having higher bit density, and the same memory performance as in the conventional planar floating gate type structure can be realized. Further, since a structure in which the memory cells MC having the planar floating gate type structure already proven as the non-volatile semiconductor memory device are stacked, reliability can be easily secured, and a user learning period can be shortened.

Further, the floating gate electrode film 109 is not formed on the both side surfaces of the whole circumference of the channel semiconductor film 103. The floating gate electrode film 109 is only formed on one side surface of the channel semiconductor film 103 in the Y direction, however, the floating gate electrode film 109 is not formed on the opposite other side surface. As a result, the back gate electrode film 121 can be arranged on the other side of the surface side, and thus there is an effect capable of further improving erasing characteristics of the memory cell MC.

In addition, since a shape in which the stacked films can be collectively processed is provided, the memory cells MC can be stacked without significantly increasing the number of processes, and thus the bit capacity per unit area can be enhanced. That is, there is an effect capable of improving a degree of integration without performing scaling down.

Further, after the spacer film 104, which corresponds to a shallow trench isolation (STI) of a typical floating gate memory cell MC, is formed, the tunnel dielectric film 108 and the floating gate electrode film 109 are formed on the channel semiconductor film 103, and further the IPD film 110 and the control gate electrode film 111M are formed by forming a recess in the spacer film 104. As described above, there are effects capable of forming through a manufacturing process flow, which is substantially the same as the typical floating gate type structure, and relatively easily controlling the shape of the floating gate electrode film 109.

### Second Embodiment

The first embodiment has been described in connection with the structure in which the control gate electrode films of the memory cell are arranged on both sides in the Z direction. However, a second embodiment will be described in connection with a non-volatile semiconductor memory device having a structure in which the control gate electrode films are arranged on both sides in the X direction.

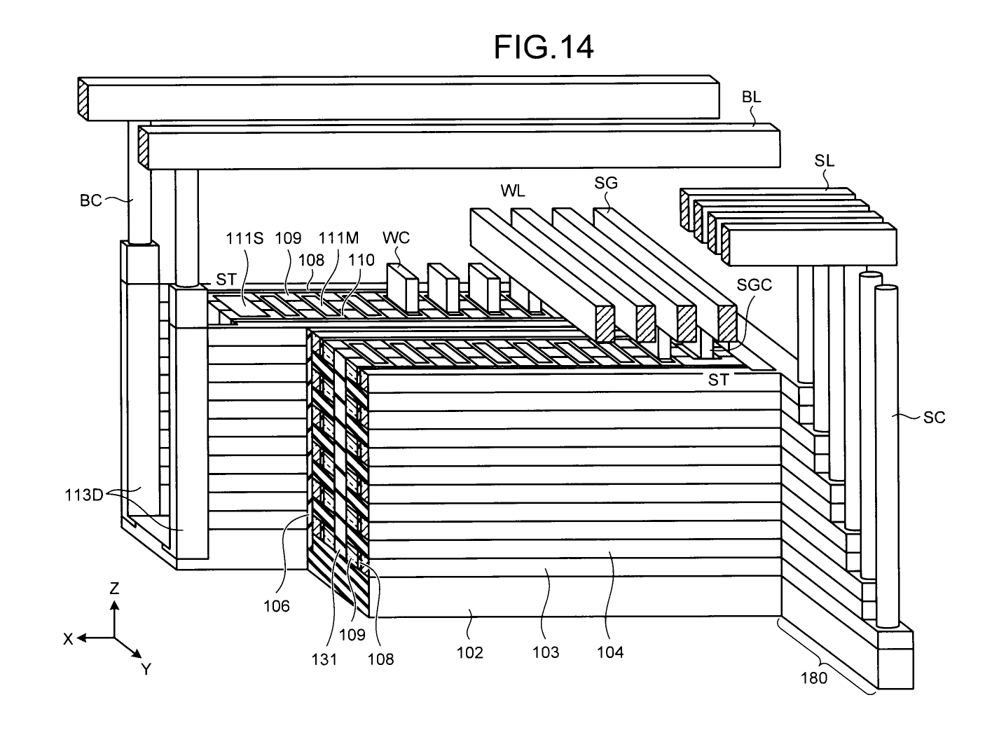

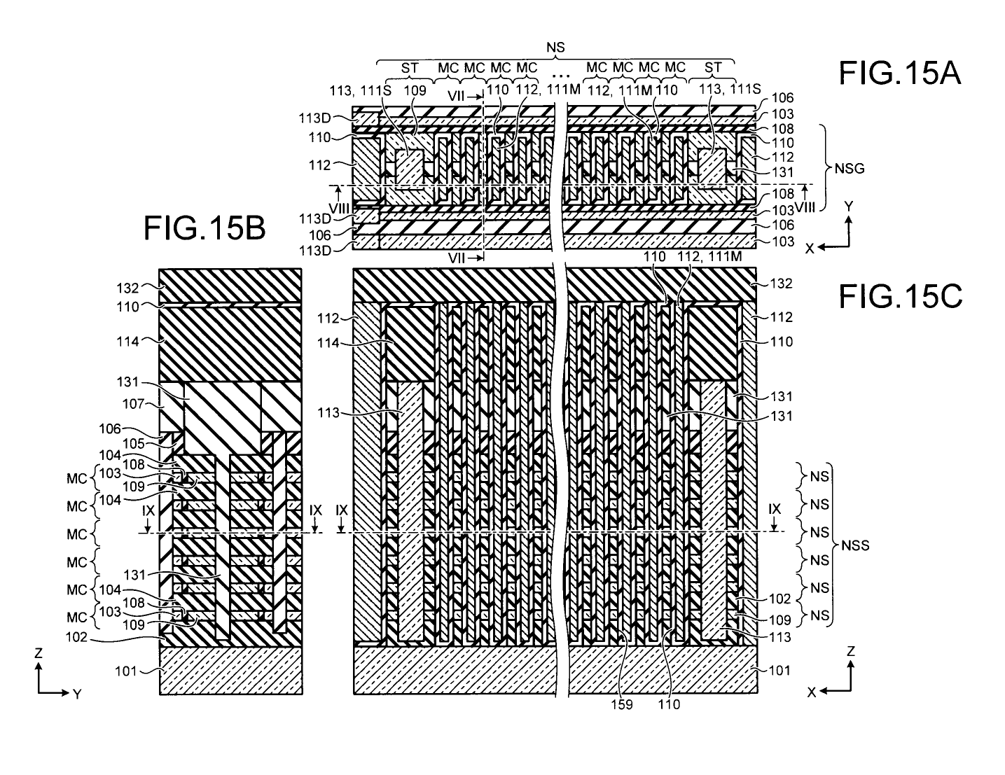

FIG. 14 is a perspective view schematically illustrating an example of a structure of a non-volatile semiconductor memory device according to the second embodiment. In FIG. 14, an appropriate portion of the non-volatile semiconductor memory device structure is abbreviated and the remnant portion is only illustrated in order to support understanding of this structure, therefore an ILD film is not illustrated. FIGS. 15A to 15C are cross-sectional views schematically illustrating an example of the structure of the non-volatile semiconductor memory device according to the second embodiment. Specifically, FIG. 15A is a cross-sectional view viewed in a direction parallel to a substrate surface at a forming position of a floating gate electrode film. FIG. 15B is a cross-sectional view taken along line VII-VII of FIG. 15A. FIG. 15C is a cross-sectional view taken along line VIII-VIII of FIG. 15A. FIG. 15A corresponds to a cross-sectional view taken along line IX-IX of FIGS. 15B and 15C. Further, in the following description, a direction in which a bit line extends in the substrate surface is defined as an X direction, a direction in which a word line perpendicular to the bit line extends in the substrate surface is defined as a Y direction, and a direction vertical to the substrate surface is defined as a Z direction.

The non-volatile semiconductor memory device has a structure in which a plurality of NAND string stacks NSS are arranged, in the X direction and the Y direction, above a semiconductor substrate 101. The NAND string stack NSS has a structure in which a plurality of NAND strings NS are stacked, in the Z direction, through spacer films 104. The NAND string NS extends in the X direction and includes a plurality of memory cell transistors MC formed in series in the X direction on one main surface of a channel semiconductor film 103, which is an active area of a sheet shape parallel to a substrate surface, in the Y direction. Here, a NAND string group NSG includes a pair of NAND string stacks NSS arranged so that forming surfaces of memory cells MC can face each other. The NAND string groups NSG are arranged on the semiconductor substrate 101 in a matrix shape. The adjacent NAND string groups NSG are isolated by a gap-fill dielectric film 106.

The memory cell MC has a floating gate type structure. The memory cell MC includes a floating gate electrode film 109 extending in the Y direction and a pair of control gate electrode films 111M which are arranged, on both sides of the floating gate electrode film 109 in the X direction, to face each other. The floating gate electrode film 109 is formed above the channel semiconductor film 103 through the tunnel dielectric film 108. The control gate electrode film 111M is provided, between the floating gate electrode films 109 of the memory cells MC adjacent to each other in the X direction, above the channel semiconductor film 103, through an inter-poly dielectric (IPD) 110. The control gate electrode film 111M is shared between the memory cells MC adjacent to each other in the Z direction. Further, the control gate electrode film 111M is shared between the memory cells MC of a pair of NAND string stacks NSS in which the forming surfaces of the memory cells MC face each other.

The spacer film 104 isolates the memory cells MC (the floating gate electrode films 109) adjacent to each other in the Z direction from each other and isolates the selection transistors ST from each other. Between the floating gate electrode films 109 of the memory cells MC, which are adjacent to each other in the Y direction and share the control gate electrode film 111M, a gap-fill dielectric film 131, which isolates the floating gate electrode films 109, is provided. The other components are substantially the same as in the first embodiment and are denoted by the same reference numerals, and the redundant description will not be repeated.

In the non-volatile semiconductor memory device having the above configuration, an arbitrary memory cell MC is selected such that a position on a plane parallel to the semiconductor substrate 101 is selected through two neighboring word lines WL sandwiching the floating gate electrode film 109 of the selected cell and one bit line BL and a stacked layer is selected through the source line SL. The memory cell MC does not individually include an impurity diffusion region that functions as the source and drain regions. By an electric field which is generated by applying a voltage to each control gate electrode films 111M so that a depletion layer is formed in the channel semiconductor film 103 under the floating gate electrode film 109 and the channel semiconductor film 103 directly below the control gate electrode films 111M, formed is a channel connected to the entire channel semiconductor film 103.

Each memory cell MC is an inversion type transistor or a depletion type transistor having no source/drain structure. As will be described later, in the structure according to the second embodiment, it is not necessary to form the control gate electrode film 111M by collectively processing layers in the complicated stacked structure described in the first embodiment, however, a voltage may be applied even to a non-selected cell next to the selected. However, in the structure of the memory cell having no impurity diffusion region, a region where high-concentration electrons exist is not present in a channel, even though Vₚₐₛₛ is applied to a non-selected cell, a program disturb or read disturb hardly occurs. The writing operation and the erasing operation on an arbitrary floating gate electrode film 109 are the same as in the first embodiment, and the redundant description will not be repeated.

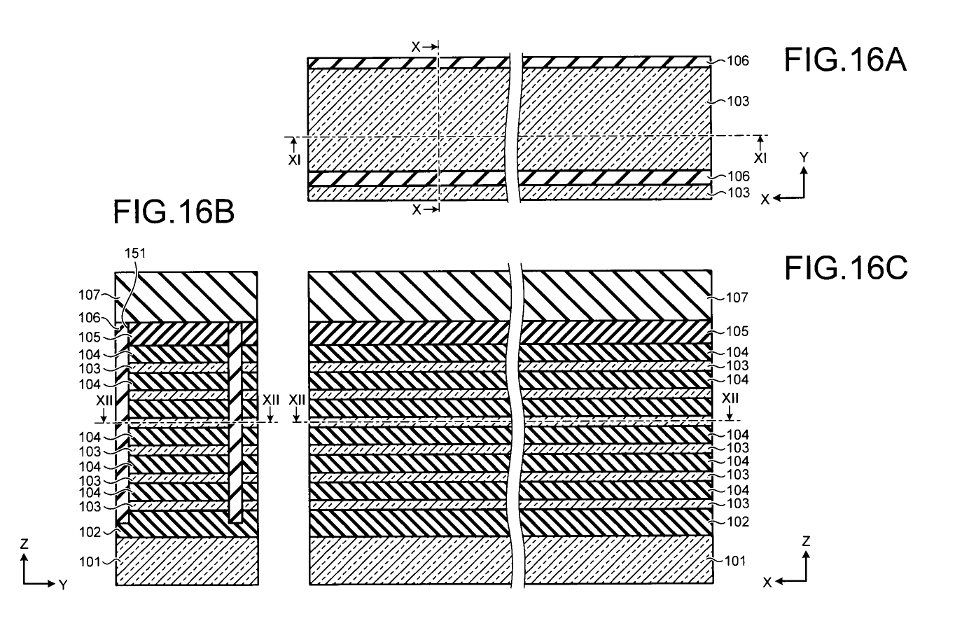

Next, a description will be made in connection with a method of manufacturing the non-volatile semiconductor memory device having the above structure. FIGS. 16A to 19C are cross-sectional views schematically illustrating an example of a method of manufacturing the non-volatile semiconductor memory device according to the second embodiment. In these drawings, FIGS. 16A to 19A are cross-sectional views viewed in a direction parallel to the substrate surface at the forming position of the floating gate electrode film, FIGS. 16B to 19B are cross-sectional views taken along line X-X of FIGS. 16A to 19A, and FIGS. 16C to 19C are cross-sectional views taken along line XI-XI of FIGS. 16A to 19A. FIGS. 16A to 19A correspond to cross-sectional views taken along line XII-XII of FIGS. 16B to 19B and FIGS. 19B and 19C.

In the following, described is an example of manufacturing a non-volatile semiconductor memory device having a structure in which 6 layers each of which includes the channel semiconductor film 103 and the spacer film 104 are stacked at a pitch of 40 nm in parallel to the semiconductor substrate 101, a half pitch in the Y direction is 62 nm, and a half pitch in the X direction is 30 nm. As a result, bit density equal to a NAND flash type memory of a two-dimensional structure in which a half pitch is 17.0 nm can be achieved. Further, a method of forming a peripheral circuit and a lead-out portion is the same as in a method of forming a typical non-volatile semiconductor memory device or a typical stacked non-volatile semiconductor memory device, and thus a detailed description thereof will not be provided.

First, as illustrated in FIGS. 16A to 16C, a peripheral circuit (not illustrated) of a non-volatile semiconductor memory device is formed on a semiconductor substrate 101. Next, an ILD film 102 is formed on the entire surface of the semiconductor substrate 101. For example, a silicon oxide film having a thickness of 100 nm may be used as the ILD film 102.

Thereafter, a plurality of layers (here, 6 layers) in which a channel semiconductor film 103 and a spacer film 104 are alternately stacked are formed on the ILD film 102. For example, an amorphous silicon film having a thickness of 15 nm may be used as the channel semiconductor film 103, and a silicon oxide film having a thickness of 25 nm may be used as the spacer film 104. Further, a hard mask film 105 is formed on the spacer film 104 of the top layer. For example, a silicon nitride film having a thickness of 50 nm may be used as the hard mask film 105. Further, it is desirable to reduce a channel width (the thickness of the channel semiconductor film 103) so as to achieve a high coupling ratio (CR) in the above structure.

Then, by collectively processing the stacked films, which includes the hard mask film 105, the spacer film 104, and the channel semiconductor film 103, using a lithography technique and an RIE technique, a trench 151, which extends in the X direction to expose a part of the ILD film 102, is formed at a predetermined pitch in the Y direction. For example, the width of the trench 151 may be set to 25 nm, and the pitch may be set to 232 nm. The trench 151 corresponds to one which divides the stacked film in association with an area for forming the NAND string group NSG, and isolates the channel semiconductor films 103 of the memory cells MC, adjacent to each other in the Y direction, in the adjacent NAND string group NSG, in FIGS. 14 and 15A to 15C.

Thereafter, a gap-fill dielectric film 106 is formed in the trench 151. The top surface of the gap-fill dielectric film 106 is planarized using a CMP technique, and so the hard mask film 105 is exposed in a region other than the position at which the trench 151 is formed. For example, a silicon oxide film formed by a CVD technique may be used as the gap-fill dielectric film 106. Then, a hard mask film 107 is formed over the entire surface of the semiconductor substrate 101. For example, a silicon nitride film having a thickness of 100 nm may be used as the hard mask film 107.

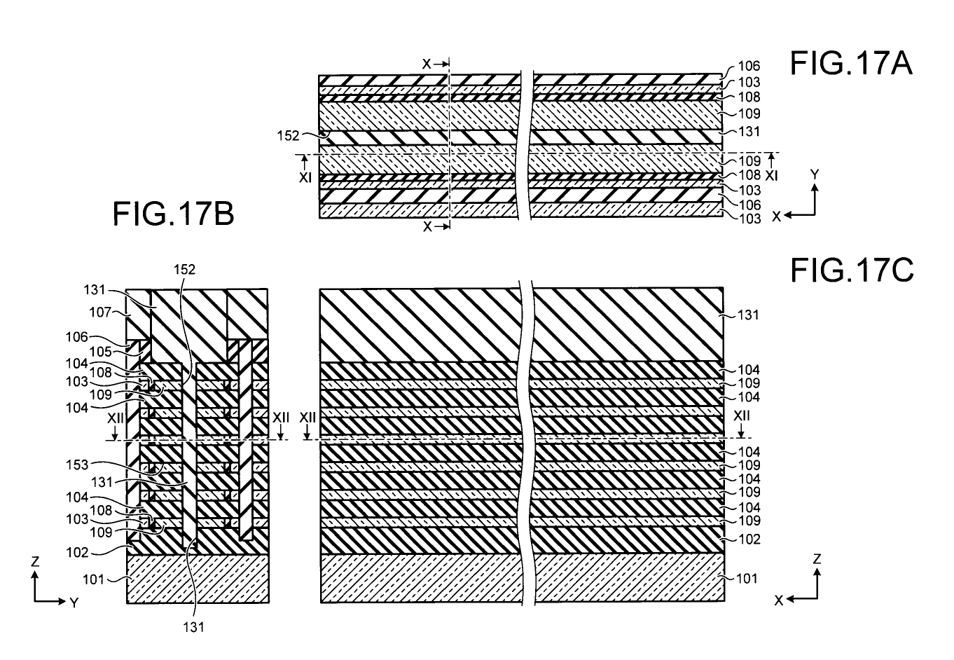

Next, as illustrated in FIGS. 17A to 17C, by collectively processing the stacked films, which includes the hard mask films 107 and 105, the spacer film 104, and the channel semiconductor film 103, using a lithography technique and an RIE technique, a trench 152, which extends in the X direction to expose a part of the ILD film 102, is formed at a predetermined pitch in the Y direction. For example, the width of the trench 152 may be set to 30 nm. The trench 152 corresponds to one which divides an area for forming the NAND string stack NSS in FIGS. 14 and 15A to 15C.

Thereafter, a space 153 is formed by forming a recess in the channel semiconductor film 103 by a predetermined amount in the Y direction by using an etching technique. For example, a wet etching technique using choline, a CDE technique, a dry etching technique using chlorine gas, or the like may be used as the etching technique. For example, the recess amount of the channel semiconductor film 103 may be set to 60 nm.

Next, a tunnel dielectric film 108 is formed on a side surface of the channel semiconductor film 103 inside the space 153. For example, the tunnel dielectric film 108 may be formed using a technique such as thermal oxidation technique and a thermal nitridation technique, and the thickness of the tunnel dielectric film 108 may be set to 8 nm. Then, a floating gate electrode film 109 is formed over the entire surface of the semiconductor substrate 101. For example, a P-doped amorphous silicon film having a thickness of 15 nm may be used as the floating gate electrode film 109. Thereafter, the floating gate electrode film 109 is etched by a dry etching technique so that the floating gate electrode film 109 can remain only in the space 153 formed by recess-etching the channel semiconductor film 103. For example, chlorine gas may be used as etching gas.

Further, the hard mask films 107 and 105 are isotropically etched from an end portion of the floating gate electrode film 109 in the Y direction by a predetermined amount. For example, a wet etching technique using a hot phosphoric acid may be used as the isotropic etching technique. For example, the recess amount of the hard mask films 107 and 105 may be set to 60 nm. The recess amount of the hard mask films 107 and 105 is set to cause the channel semiconductor film 103 to be protected in a self-aligning manner when an electrode pattern forming trench is formed later, similarly to the first embodiment.

Thereafter, the gap-fill dielectric film 131 is formed in the trench 152, and a planarization process is performed using a CMP technique until the hard mask film 107 is exposed in an area other than the forming position of the trench 152. For example, a silicon oxide film formed by a CVD technique may be used as the gap-fill dielectric film 131.

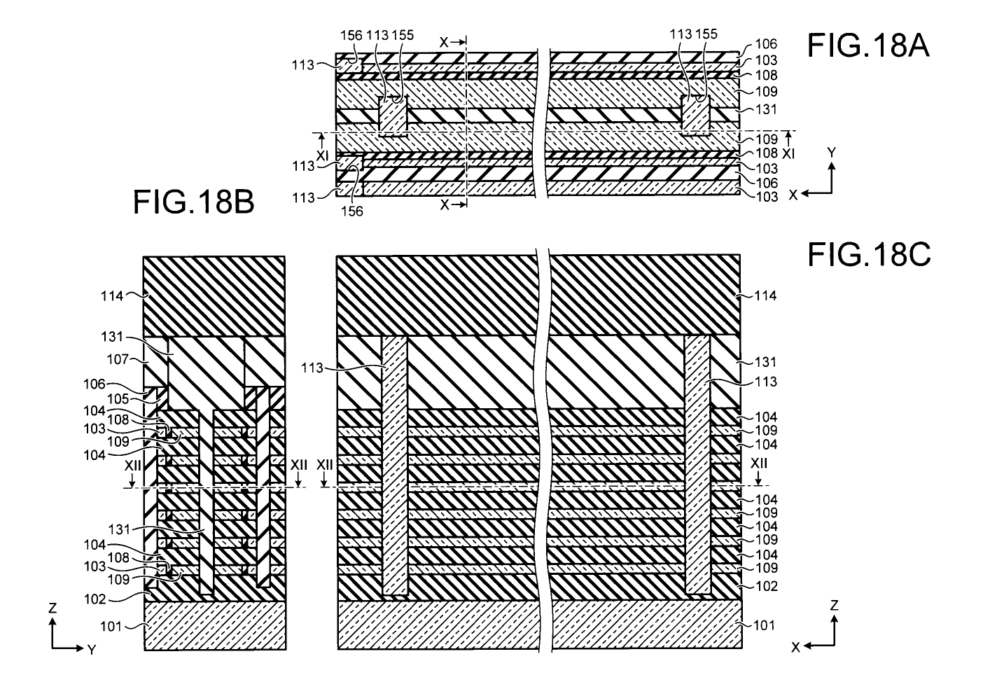

Next, as illustrated in FIGS. 18A to 18C, a selection gate electrode film-forming trench 155 and a drain region connection contact forming trench 156 are formed by a lithography technique and an RIE technique. The selection gate electrode film-forming trench 155 is formed by collectively processing the stacked films so that the floating gate electrode films 109, the spacer film 104, and the gap-fill dielectric film 131 of a pair of NAND string stacks NSS, which face each other, in the forming regions of the selection transistors ST can be partially removed and so the floating gate electrode film 109 of the lowest layer can be exposed. The drain region connection contact forming trench 156 is formed by collectively processing the stacked films so that the floating gate electrode film 109 of the lowest layer can be exposed in part of the drain region of each NAND string stack NSS.

Thereafter, a conductive film 113 is filled in the selection gate electrode film-forming trench 155 and the drain region connection contact forming trench 156. Then, a planarization process is performed using a CMP technique. For example, an As-doped amorphous silicon film may be used as the conductive film 113. As a result, in the forming region of the selection transistor ST, a common connection between the floating gate electrode films 109 of the memory cells MC facing each other through the gap-fill dielectric film 131 therebetween is made by the conductive film 113. The selection gate electrode film 111S is configured with the floating gate electrode film 109 and the conductive film 113. The drain region connection contact 113D is formed in the drain region connection contact forming trench 156.

In addition, a hard mask film 114, which will be used later for processing the control gate electrode film 111M, is formed over the semiconductor substrate 101. For example, a silicon nitride film having a thickness of 150 nm may be used as the hard mask film 114.

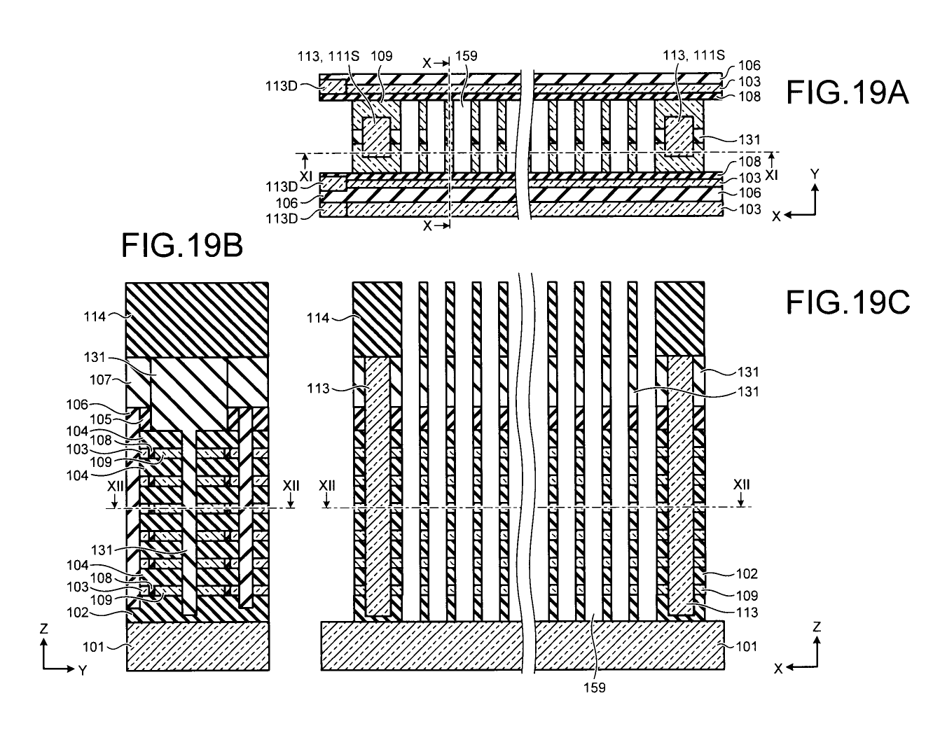

Next, as illustrated in FIGS. 19A to 19C, by collectively processing the gap-fill dielectric film 131, the hard mask film 114, the floating gate electrode film 109, and the spacer film 104 in the memory cell forming region by a lithography technique and an RIE technique, a control gate electrode film-forming trench 159, which functions as a mold of the control gate electrode film 111M, is formed to expose the bottom surface of the ILD film 102. For example, the control gate electrode film-forming trench 159 having the width of 45 nm in the X direction may be formed at a pitch 60 nm in the X direction.

Further, the hard mask films 107 and 105 are formed to protect the channel semiconductor film 103 from being etched when the control gate electrode film-forming trench 159 is processed. Thus, even though precise overlay is not performed, the channel semiconductor film 103 of the memory cell MC can be protected in a self-aligning manner. The hard mask films 107 and 105 are preferably made of a material capable of easily obtaining selectivity when the control gate electrode film-forming trench 159 is processed. The hard mask films 107 and 105 may be formed of a dielectric film made of SiBN, SiCN, alumina, titania, hafnia, zirconia, or the like, instead of the silicon nitride film.

Next, as illustrated in FIGS. 15A to 15C, an IPD film 110 is formed over the entire surface of the semiconductor substrate 101. The IPD film 110 is formed to conformally cover the inside of the control gate electrode film-forming trench 159. For example, an alumina film having a thickness of 11 nm may be used as the IPD film 110.

Then, a conductive film 112 is filled in the control gate electrode film-forming trench 159. For example, a TaN/W stacked film having a thickness of 50 nm formed by a CVD technique may be used as the conductive film 112. Thereafter, a portion of the conductive film 112 formed in a region other than the control gate electrode film-forming trench 159 is removed using a CMP technique.

Thereafter, a dielectric film 132 is formed over the entire surface of the semiconductor substrate 101. For example, a silicon nitride film having a thickness of 30 nm formed by an LPCVD technique may be used as the dielectric film 132. As a result, the conductive film 112 filled in the control gate electrode film-forming trench 159 becomes the control gate electrode film 111M. As described above, in the structure of the second embodiment, there is an advantage of relatively easier metallization of the control gate electrode film 111M.

Then, an ILD film is formed, and thereafter, a contact plug and a wiring are formed. However, the contact plug and the wiring may be formed using a known technique, and thus a detailed description thereof will not be provided. Through the above process, the non-volatile semiconductor memory device according to the second embodiment is obtained.

Further, there may be provided a configuration in which a back gate electrode film is formed, on a surface opposite to the memory cell forming surface of the channel semiconductor film 103, through a gate dielectric film, similarly to FIG. 13 of the first embodiment.

In the second embodiment, it is sufficient if the control gate electrode film-forming trench 159 is formed in the stacked film including the channel semiconductor film 103 and the spacer film 104 when the control gate electrode film 111M is processed. Thus, there is an advantage in that collective processing is easier than that of the first embodiment.

### Third Embodiment

A third embodiment will be described in connection with a manufacturing method capable of further reducing a stacked film thickness of a memory cell by processing an end portion of a floating gate electrode film in the non-volatile semiconductor memory device having the structure according to the first embodiment illustrated in FIG. 1 and FIGS. 2A to 2C.

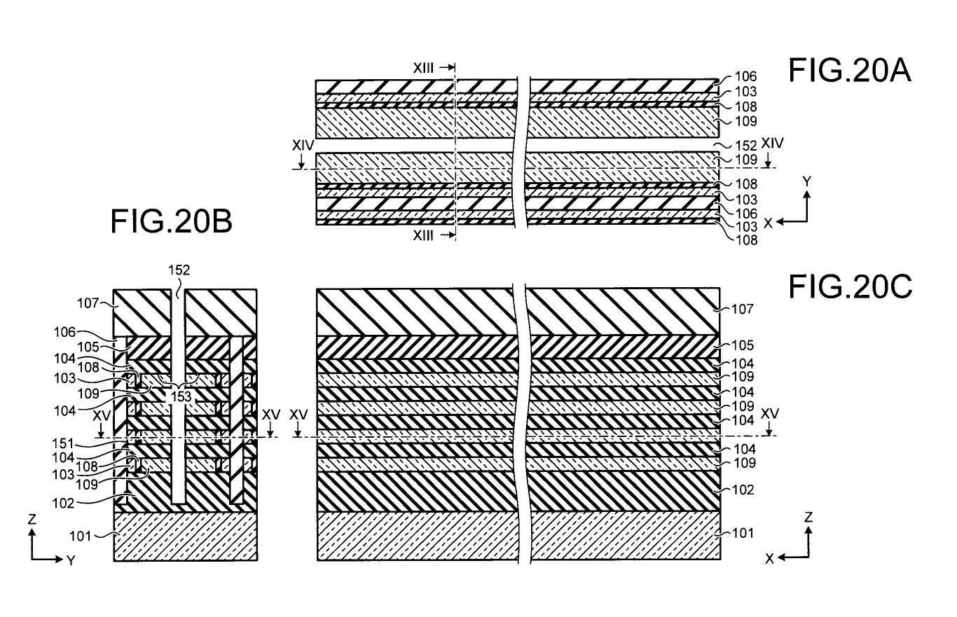

FIGS. 20A to 23C are cross-sectional views schematically illustrating an example of a process of a method of manufacturing a non-volatile semiconductor memory device according to a third embodiment. In these drawings, FIGS. 20A to 23A are cross-sectional views viewed in a direction parallel to a substrate surface at a forming position of a floating gate electrode film, FIGS. 20B to 23B are cross-sectional views taken along line XIII-XIII of FIGS. 20A to 23A, and FIGS. 20C to 23C are cross-sectional views taken along line XIV-XIV of FIGS. 20A to 23A. FIGS. 20A to 23A correspond to cross-sectional views taken along line XV-XV of FIGS. 20B to 23B and FIGS. 10C and 23C.

In the following, a description will be made in connection with an example capable of achieving the same bit density as in a NAND flash type memory of a two-dimensional structure whose half pitch is 21.2 nm when 4 layers each of which includes a channel semiconductor film 103 and a spacer film 104 are stacked in parallel to a semiconductor substrate 101.

First, similarly to the process according to the first embodiment illustrated in FIGS. 3A to 6C, a tunnel dielectric film 108 is formed in a space 153 between spacer films 104 adjacent to each other in a Z direction, and further a process of filling the floating gate electrode film 109 in the space 153 is performed. That is, as illustrated in FIGS. 20A to 20C, a peripheral circuit (not illustrated) of a non-volatile semiconductor memory device is formed on a semiconductor substrate 101. Thereafter, an ILD film 102 is formed above the entire surface of the semiconductor substrate 101. For example, a silicon oxide film having a thickness of 100 nm may be used as the ILD film 102.

Thereafter, a plurality of layers (here, 4 layers) in which a channel semiconductor film 103 and a spacer film 104 are alternately stacked are formed on the ILD film 102. For example, an amorphous silicon film having a thickness of 20 nm may be used as the channel semiconductor film 103, and a silicon oxide film having a thickness of 20 nm may be used as the spacer film 104.

Further, a hard mask film 105 is formed on the spacer film 104 of the top layer. For example, a silicon nitride film having a thickness of 50 nm may be used as the hard mask film 105. Thereafter, by collectively processing the stacked films, which includes the hard mask film 105, the spacer film 104, and the channel semiconductor film 103, using a lithography technique and an RIE technique, a trench 151, which extends in the X direction to expose a part of the ILD film 102, is formed at a predetermined pitch in the Y direction. For example, the width of the trench 151 may be set to 25 nm, and the pitch may be set to 288 nm. The trench 151 corresponds to one which divides the stacked film in association with an area for forming the NAND string group NSG, and isolates the channel semiconductor films 103 of the memory cells MC, adjacent to each other, in the NAND string groups NSG adjacent to each other in the Y direction, in FIG. 1 and FIGS. 2A to 2C.

Thereafter, a gap-fill dielectric film 106 is formed in the trench 151. The top surface of the gap-fill dielectric film 106 is planarized using a CMP technique, and so the hard mask film 105 is exposed in a region other than the position at which the trench 151 is formed. For example, a silicon oxide film formed by a CVD technique may be used as the gap-fill dielectric film 106. Then, a hard mask film 107 is formed over the entire surface of the semiconductor substrate 101. For example, a silicon nitride film having a thickness of 100 nm may be used as the hard mask film 107.

Next, by collectively processing the stacked films, which includes the hard mask films 107 and 105, the spacer film 104, and the channel semiconductor film 103, using a lithography technique and an RIE technique, a trench 152, which extends in the X direction to expose a part of the ILD film 102, is formed at a predetermined pitch in the Y direction. For example, the width of the trench 152 may be set to 40 nm. The trench 152 corresponds to one which divides an area for forming the NAND string stack NSS in FIG. 1 and FIGS. 2A to 2C.

Thereafter, a space 153 is formed by etching the channel semiconductor film 103 by a predetermined amount in the Y direction. For example, a wet etching technique using choline, a CDE technique, a dry etching technique using chlorine gas, or the like may be used as the etching technique. For example, the recess amount of the channel semiconductor film 103 may be set to 50 nm.

Next, a tunnel dielectric film 108 is formed on a side surface of the channel semiconductor film 103 inside the space 153. For example, the tunnel dielectric film 108 may be formed using a technique such as plasma oxidation technique and a plasma nitridation technique. For example, the thickness of the tunnel dielectric film 108 may be set to 8 nm. Then, a floating gate electrode film 109 is formed over the entire surface of the semiconductor substrate 101. For example, a P-doped amorphous silicon film having a thickness of 20 nm may be used as the floating gate electrode film 109. Thereafter, the floating gate electrode film 109 is etched by a dry etching technique so that the floating gate electrode film 109 can remain only in the space 153. For example, chlorine gas may be used as etching gas.

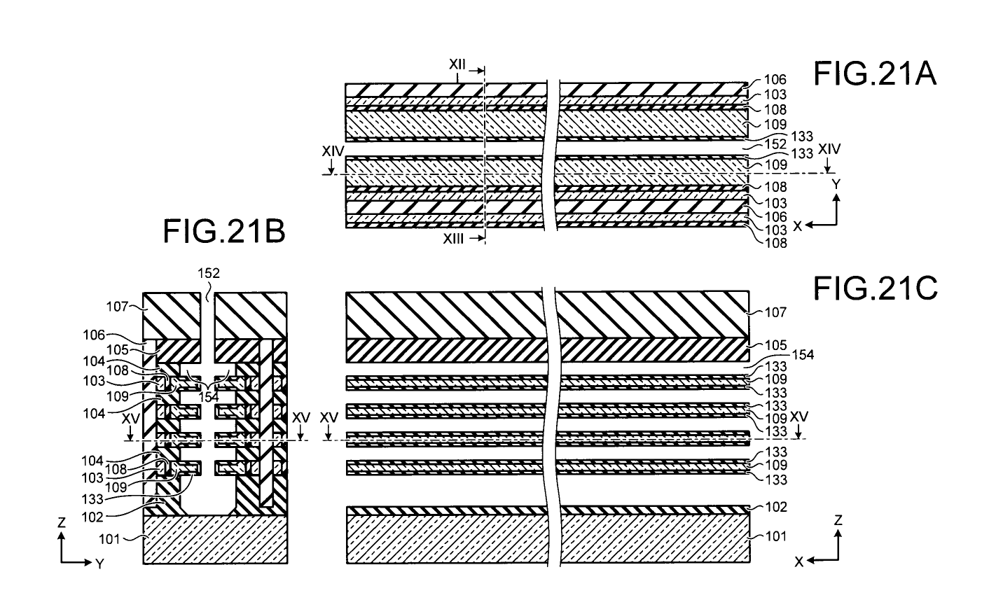

Next, as illustrated in FIGS. 21A to 21C, a recess is formed in the spacer film 104 by an isotropic etching technique. The recess is formed in the spacer film 104, in a predetermined depth, from an end portion of the floating gate electrode film 109, which configures the side wall of the trench 152, in the Y direction. As a result, formed is a space 154 which is to be filled with the control gate electrode film 111M. For example, a wet etching technique or a dry etching technique using HF/NH₃ gas may be used as the isotropic etching. For example, the recess amount of the spacer film 104 may be set to 40 nm.

Then, an oxide film 133 is formed on the surface of the floating gate electrode film 109. For example, a silicon oxide film having a thickness of 5 nm formed by plasma oxidizing the surface of the floating gate electrode film 109 may be used as the oxide film 133.

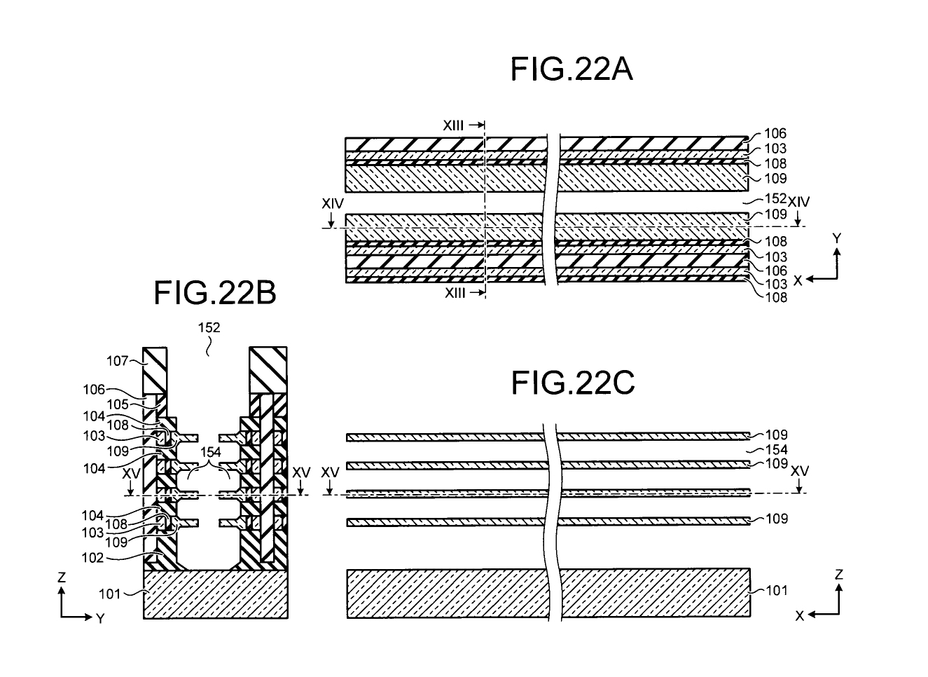

Next, as illustrated in FIGS. 22A to 22C, the oxide film 133 formed on the surface of the floating gate electrode film 109 is removed using an isotropic etching technique so that a portion (hereinafter, referred to as “end portion”) of the floating gate electrode film 109, which protrudes from an end portion of the spacer film 104 in the Y direction, can be slimmed. For example, a wet etching technique or a dry etching technique using HF/NH₃ gas may be used as the isotropic etching.

Thereafter, the hard mask films 107 and 105 are isotropically etched from the end portion of the floating gate electrode film 109 by a predetermined amount. For example, a wet etching technique using a hot phosphoric acid may be used as the isotropic etching technique. For example, the recess amount of the hard mask films 107 and 105 may be set to 50 nm.

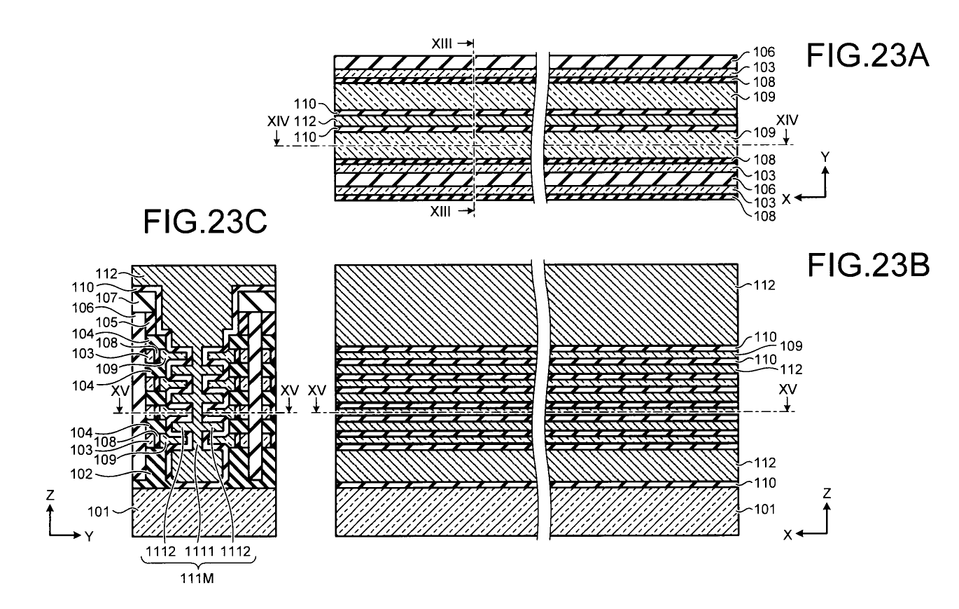

Next, as illustrated in FIGS. 23A to 23C, an IPD film 110 is formed over the entire surface of the semiconductor substrate 101. The IPD film 110 is formed to conformally cover the inside of the space 154. A SiO—SiN—SiO (ONO) film having a thickness of 10 nm may be used as the IPD film 110. Further, a conductive film 112 is formed over the entire surface of the semiconductor substrate 101. Here, the conductive film 112 is formed to be filled in the trench 152 and the space 154 formed in the trench 152. For example, a P-doped polysilicon film having a thickness of 50 nm may be used as the conductive film 112. The conductive film 112 functions as the control gate electrode film 111M in the forming region of the memory cell MC. The electrode forming section 1112 is formed, in the space 154 on both sides of the floating gate electrode film 109 in the Z direction, with the IPD film 110 interposed. The common connecting section 1111, which connects the electrode forming sections 1112 stacked in the Z direction, is formed in the trench 152.

Thereafter, performed is a process of forming the selection gate electrode film-forming trench 155 and the drain region connection contact forming trench 156 illustrated in FIGS. 9A to 9C according to the first embodiment. However, the process is the same as the process described in the first embodiment, and thus the redundant description will not be repeated. Here, a silicon nitride film having a thickness of 80 nm is used as the hard mask film 114, and the electrode pattern forming trench 157 is formed at a half pitch of 25 nm.

In the third embodiment, after the spacer film 104 corresponding to the STI of the typical floating gate NAND flash type memory is formed, the tunnel dielectric film 108 and the floating gate electrode film 109 are formed on the channel semiconductor film 103. Next, a recess is formed in the spacer film 104, and further the end portion of the floating gate electrode film 109 is slimmed. As a result, there is an effect capable of forming a space in which the IPD film 110 and the control gate electrode film 111M are formed by the substantially same manufacturing process flow of the typical NAND flash type memory of floating gate type. Further, the final structure of the memory cell MC hardly differs in shape from the typical floating gate type structure, and the almost same memory performance as in the conventional floating gate type structure can be realized. In addition, since the stacked film thickness per layer can be reduced, it is effective, particularly, when the number of stacked layers is increased.

### Fourth Embodiment

A fourth embodiment will be described in connection with a manufacturing method capable of further reducing a projected area of a memory cell by processing an end portion of a floating electrode film in the non-volatile semiconductor memory device having the structure according to the first embodiment illustrated in FIG. 1 and FIGS. 2A to 2C.

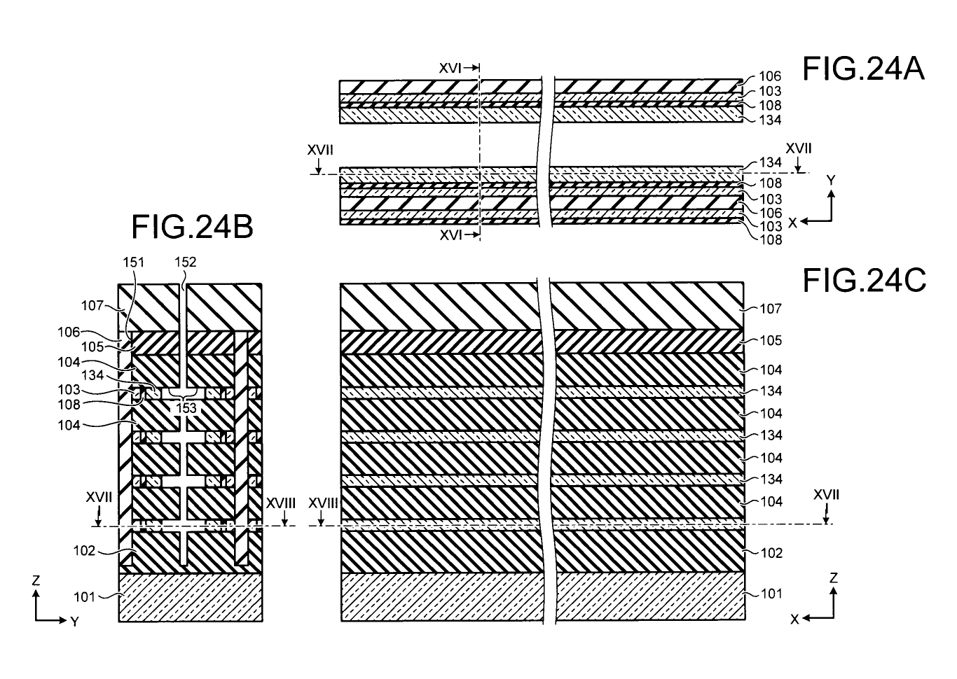

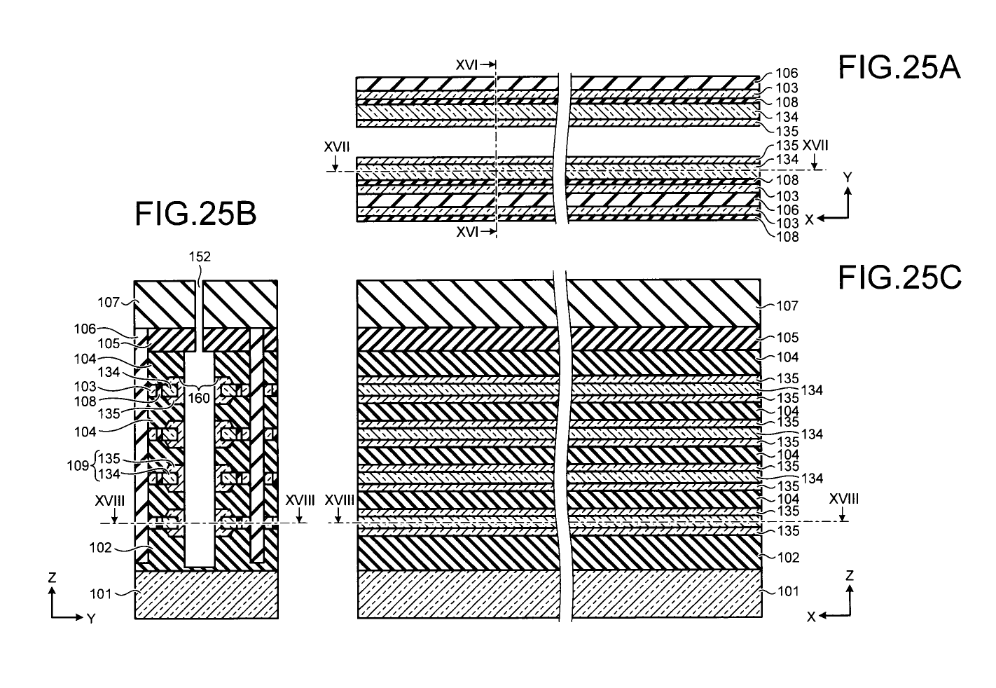

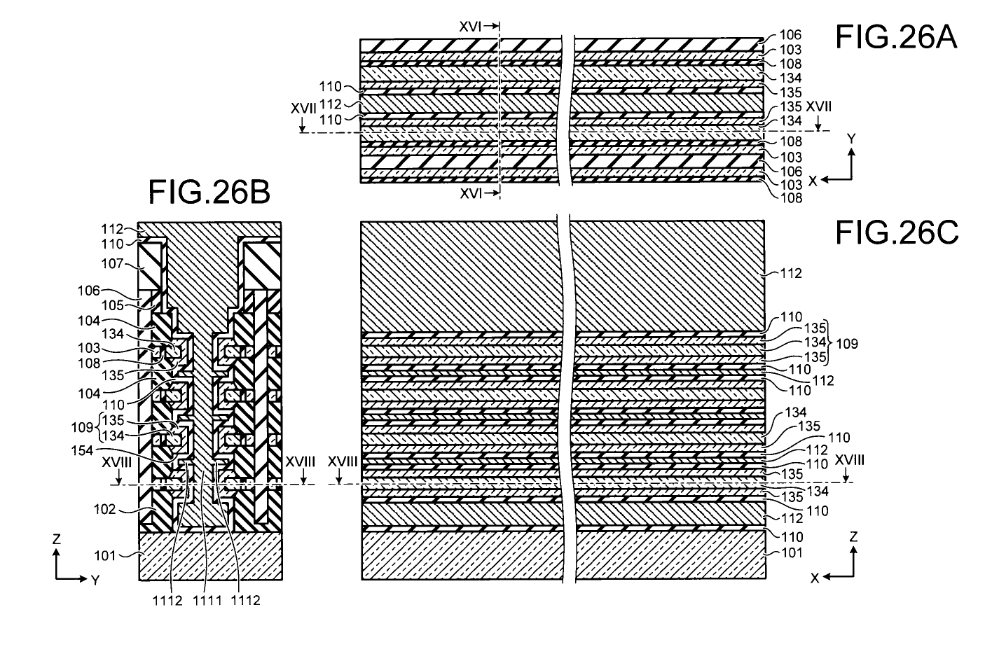

FIGS. 24A to 26C are cross-sectional views schematically illustrating an example of a process of a method of manufacturing a non-volatile semiconductor memory device according to a fourth embodiment. In these drawings, FIGS. 24A to 24C are cross-sectional views viewed in a direction parallel to a substrate surface at a forming position of a floating gate electrode film, FIGS. 25A to 25C are cross-sectional views taken along line XVI-XVI of FIGS. 24A to 24C, and FIGS. 26A to 26C are cross-sectional views taken along line XVII-XVII of FIGS. 24A to 24C. FIGS. 24A to 26A correspond to cross-sectional views taken along line XVIII-XVIII of FIGS. 24B to 26B and FIGS. 24C and 26C.

In the following, a description will be made in connection with an example capable of achieving the same bit density as in a NAND flash type memory of a two-dimensional structure (a planar floating gate type structure) whose half pitch is 19.0 nm when 4 layers each of which includes a channel semiconductor film 103 and a spacer film 104 are stacked in parallel to a semiconductor substrate 101.

First, as illustrated in FIGS. 24A to 24C, a peripheral circuit (not illustrated) of a non-volatile semiconductor memory device is formed on a semiconductor substrate 101. Thereafter, an ILD film 102 is formed above the entire surface of the semiconductor substrate 101. For example, a silicon oxide film having a thickness of 100 nm may be used as the ILD film 102.

Subsequently, a plurality of layers (here, 4 layers) in which a channel semiconductor film 103 and a spacer film 104 are alternately stacked are formed on the ILD film 102. For example, an amorphous silicon film having a thickness of 20 nm may be used as the channel semiconductor film 103, and a silicon oxide film having a thickness of 75 nm may be used as the spacer film 104.

Further, a hard mask film 105 is formed on the spacer film 104 of the top layer. For example, a silicon nitride film having a thickness of 50 nm may be used as the hard mask film 105. Thereafter, by collectively processing the stacked films, which includes the hard mask film 105, the spacer film 104, and the channel semiconductor film 103, using a lithography technique and an RIE technique, a trench 151, which extends in the X direction to expose a part of the ILD film 102, is formed at a predetermined pitch in the Y direction. For example, the width of the trench 151 may be set to 25 nm, and the pitch may be set to 232 nm. The trench 151 corresponds to one which divides the stacked film in association with an area for forming the NAND string group NSG, and isolates the channel semiconductor films 103 of the memory cells MC, adjacent to each other, in the NAND string groups NSG adjacent to each other in the Y direction, in FIG. 1 and FIGS. 2A to 2C.

Thereafter, a gap-fill dielectric film 106 is formed in the trench 151. The top surface of the gap-fill dielectric film 106 is planarized using a CMP technique, and so the hard mask film 105 is exposed in a region other than the position at which the trench 151 is formed. For example, a silicon oxide film formed by a CVD technique may be used as the gap-fill dielectric film 106. Then, a hard mask film 107 is formed over the entire surface of the semiconductor substrate 101. For example, a silicon nitride film having a thickness of 100 nm may be used as the hard mask film 107.

Next, a mask film (not illustrated) is formed over the entire surface of the semiconductor substrate 101. By collectively processing the stacked films, which includes the hard mask films 107 and 105, the spacer film 104, and the channel semiconductor film 103, using a lithography technique and an RIE technique, a trench 152, which extends in the X direction to expose a part of the ILD film 102, is formed at a predetermined pitch in the Y direction. For example, the width of the trench 152 may be set to 30 nm. The trench 152 divides an area for forming the NAND string stack NSS in FIG. 1 and FIGS. 2A to 2C. For example, a CVD carbon film may be used as the mask film. After the trench 152 is formed, the mask film is removed.

Thereafter, a space 153 is formed by forming a recess in the channel semiconductor film 103 by a predetermined amount in the Y direction by using an etching technique. For example, a wet etching technique using choline, a CDE technique, a dry etching technique using chlorine gas, or the like may be used as the etching technique. For example, the recess amount of the channel semiconductor film 103 may be set to 60 nm.

Next, a tunnel dielectric film 108 is formed on a side surface of the channel semiconductor film 103 inside the space 153. For example, the tunnel dielectric film 108 may be formed using a technique such as plasma oxidation technique and a thermal nitridation technique. For example, the thickness of the tunnel dielectric film 108 may be set to 8 nm. Then, a conductive film 134 functioning as part of the floating gate electrode film 109 is formed over the entire surface of the semiconductor substrate 101. For example, a P-doped amorphous silicon film having a thickness of 20 nm may be used as the conductive film 134. Thereafter, the conductive film 134 is continuously etched by a dry etching technique so that the conductive film 134 is removed by a predetermined amount (e.g., 30 nm) from an end portion of the space 153 (an end portion of the spacer film 104 in the Y direction), formed by recess-etching the channel semiconductor film 103. For example, chlorine gas may be used as etching gas.

Next, as illustrated in FIGS. 25A to 25C, the spacer film 104 is isotropically etched by an isotropic etching technique. Here, etching of the spacer film 104 isotropically proceeds from an end portion of conductive film 134 in the Y direction. As a result, in the spacer film 104, a space 160 of a substantially bowl shape is formed around the conductive film 134. For example, a wet etching technique or a dry etching technique using HF/NH₃ gas may be used as the isotropic etching. For example, the recess amount of the spacer film 104 may be set to 20 nm.

Then, a conductive film 135 functioning as part of the floating gate electrode film 109 is formed over the entire surface of the semiconductor substrate 101, and the conductive film 135 is etched by a dry etching technique to remain only in the space 160. For example, a P-doped amorphous silicon film having a thickness of 20 nm may be used as the conductive film 135. For example, chlorine gas may be used as etching gas. The floating gate electrode film 109 is configured with the conductive films 134 and 135.

Next, as illustrated in FIGS. 26A to 26C, the spacer film 104 is isotropically etched by a predetermined amount from an end portion of the conductive film 135, which configures the sidewall of the trench 152, in the Y direction. As a result, formed is a space 154 which is to be filled with the control gate electrode film 111M. For example, a wet etching technique or a dry etching technique using HF/NH₃ gas may be used as the isotropic etching. For example, the recess amount of the spacer film 104 may be set to 30 nm.

In addition, the hard mask films 107 and 105 are isotropically etched by a predetermined amount. For example, a wet etching technique using a hot phosphoric acid may be used as the isotropic etching technique. For example, the recess amount of the hard mask films 107 and 105 may be set to 70 nm.

Next, an IPD film 110 is formed over the entire surface of the semiconductor substrate 101. The IPD film 110 is formed to conformally cover the inside of the space 154. A SiN—SiO—SiN—SiO (NONO) film having a thickness of 11 nm may be used as the IPD film 110. Further, a conductive film 112 functioning as the control gate electrode film 111M is formed over the entire surface of the semiconductor substrate 101. Here, the conductive film 112 is formed to be filled in the trench 152 and the space 154 formed in the trench 152. For example, a P-doped polysilicon film having a thickness of 50 nm may be used as the conductive film 112. As a result, the conductive film 112 has a structure in which the electrode forming section 1112 is formed, in the space 154 between the floating gate electrode films 109, with the IPD film 110 interposed, and the electrode forming sections 1112 stacked in the Z direction are connected to each other by the common connecting section 1111 extending in the Z direction.

Thereafter, performed is a process of forming the selection gate electrode film-forming trench 155 and the drain region connection contact forming trench 156 illustrated in FIGS. 9A to 9C according to the first embodiment. However, the process is the same as the process described in the first embodiment, and thus the redundant description will not be repeated. Here, a silicon nitride film having a thickness of 80 nm formed by an LPCVD technique is used as the hard mask film 114, and the electrode pattern forming trench 157 is formed at a half pitch of 25 nm.

In the fourth embodiment, after the spacer film 104 corresponding to the STI of the typical NAND flash type memory of floating gate type is formed, the tunnel dielectric film 108 and the conductive film 134 functioning as the floating gate electrode film 109 are formed on the channel semiconductor film 103. Next, a recess is formed around the end portion of the spacer film 104, the conductive film 135 is filled in the recess, and as a result the end portion of the floating gate electrode film 109 extends in the Y direction. As a result, since a surface area of the floating gate electrode film 109 is increased, effects capable of suppressing the length of the floating gate electrode film 109 and reducing a plane area of the memory cell MC can be obtained in addition to the effects of the first embodiments. Further, the structure according to the fourth embodiment is appropriate for memory cells of a relatively small number of stacked layers.

### Fifth Embodiment

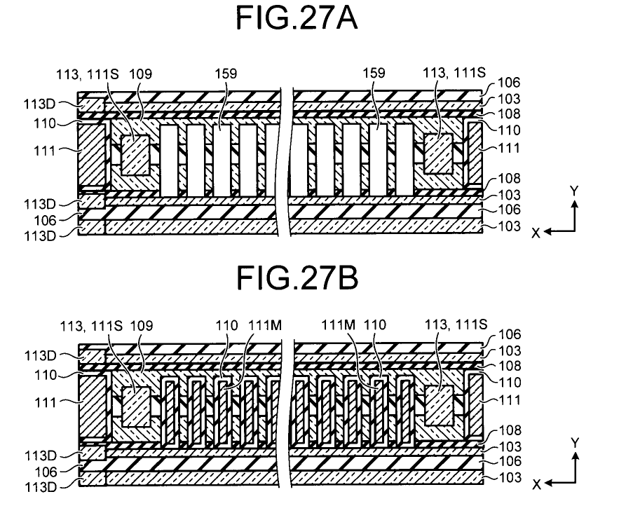

FIGS. 27A and 27B are views illustrating an example of a cross-sectional structure in the process of manufacturing the non-volatile semiconductor memory device according to the second embodiment. Here, the figures illustrate cross-sectional views viewed in a direction parallel to a substrate surface at a forming position of a floating gate electrode film 109. As illustrated in FIG. 27A, when the control gate electrode film-forming trench 159 is etched, a processing fluctuation occurs, and so, for example, the position of the control gate electrode film-forming trench 159 may be deviated in a Y direction. FIG. 27A illustrates an example in which the position of the control gate electrode film-forming trench 159 is deviated in a negative Y direction, and so the tunnel dielectric film 108 is etched off.

Thereafter, when the IPD film 110 and the control gate electrode film 111M are formed in the control gate electrode film-forming trench 159, the control gate electrode film 111M is formed, on the side surface of the channel semiconductor film 103, through the IPD film 110 since the tunnel dielectric film 108 is removed from the side surface of the control gate electrode film-forming trench 159 in the negative Y direction as illustrated in FIG. 27B.

When the control gate electrode film 111M is close to the channel semiconductor film 103 as described above, there occurs a problem in that a tunneling current flows from a channel directly to the control gate electrode film 111M. That is, in the forming method described in the second embodiment, there may occurs a situation in which the IPD film 110 only exists between the channel semiconductor film 103 and the control gate electrode film 111M due to a processing fluctuation. In this case, a leakage current from the channel semiconductor film 103 to the control gate electrode film 111M may occur. In addition, on the side surface of the control gate electrode film-forming trench 159 in the positive Y direction, the floating gate electrode film 109 may not be divided for each memory cell MC as illustrated in FIG. 27B.

In this regard, the fifth embodiment will be described in connection with a method of manufacturing a non-volatile semiconductor memory device capable of preventing the above problem from occurring in the non-volatile semiconductor memory device having the structure according to the second embodiment illustrated in FIGS. 14 and 15A to 15C.

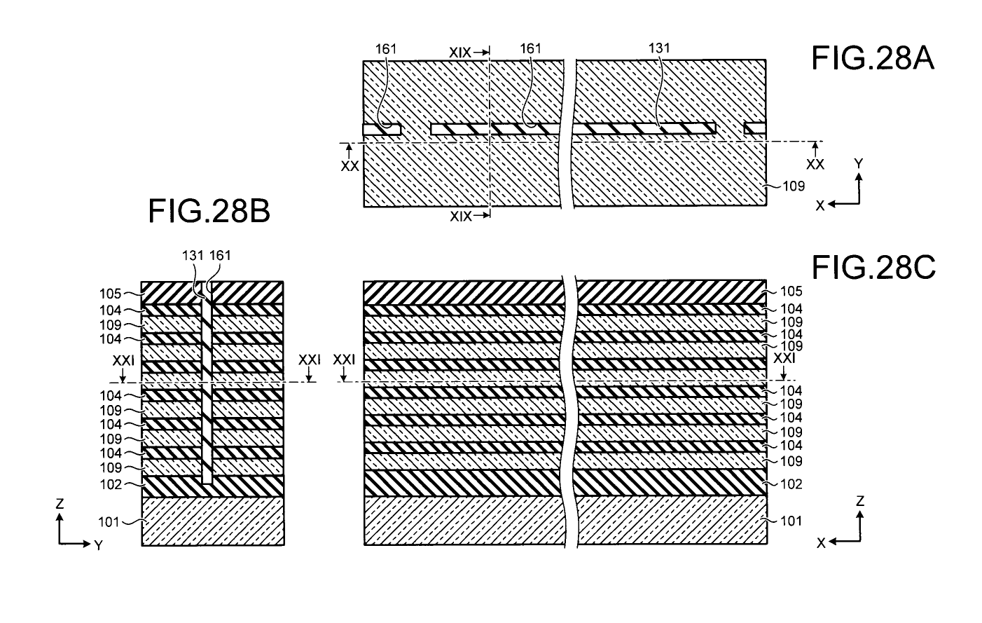

FIGS. 28A to 34C are cross-sectional views schematically illustrating an example of a process of a method of manufacturing a non-volatile semiconductor memory device according to a fifth embodiment. In these drawings, FIGS. 28A to 34A are cross-sectional views viewed in a direction parallel to a substrate surface at a forming position of a floating gate electrode film, FIGS. 28B to 34B are cross-sectional views taken along line XIX-XIX of FIGS. 28A to 34A, and FIGS. 28C to 34C are cross-sectional views taken along line XX-XX of FIGS. 28A to 34A. FIGS. 28A to 34A correspond to cross-sectional views taken along line XXI-XXI of FIGS. 28B to 34B and FIGS. 28C and 34C.

First, as illustrated in FIGS. 28A to 28C, a peripheral circuit (not illustrated) of a non-volatile semiconductor memory device is formed on a semiconductor substrate 101. Next, an ILD film 102 between the layers configuring the memory cells is formed above the entire surface of the semiconductor substrate 101. For example, a silicon oxide film having a thickness of 100 nm may be used as the ILD film 102.

Thereafter, a plurality of layers in which a floating gate electrode film 109 and a spacer film 104 are alternately stacked are formed on the ILD film 102. Here, 6 layers each of which includes a floating gate electrode film 109 and a spacer film 104 are stacked. For example, a P-doped amorphous silicon film having a thickness of 30 nm may be used as the floating gate electrode film 109, and a silicon oxide film having a thickness of 25 nm may be used as the spacer film 104. Further, a hard mask film 105 is formed on the spacer film 104 of the top layer. For example, a silicon nitride film having a thickness of 50 nm may be used as the hard mask film 105.

Then, by collectively processing the stacked films, which includes the hard mask film 105, the spacer film 104, and the floating gate electrode film 109, using a lithography technique and an RIE technique, a trench 161, which isolates the floating gate electrode film 109 between the memory cells MC adjacent to each other in the Y direction, is formed to exposes part of the ILD film 102. The trench 161 has a shape extending in the X direction, but is not formed in an area in which a selection gate electrode film is to be formed. That is, the trench 161 is provided, between selection gate electrode film-forming regions adjacent to each other in the X direction, at a predetermined pitch in the Y direction. The pitch in the Y direction is set to a dimension of the NAND string group NSG faced by the memory cell MC in the Y direction in FIGS. 14 and 15A to 15C. For example, the width of the trench 161 in the Y direction may be set to 30 nm, and the pitch in the Y direction may be set to 240 nm.

Thereafter, the gap-fill dielectric film 131 is formed in the trench 161, and the top surface of the gap-fill dielectric film 131 is planarized using a CMP technique until the hard mask film 105 is exposed in an area other the forming position of the trench 161. For example, a silicon oxide film formed by a CVD technique may be used as the gap-fill dielectric film 131.

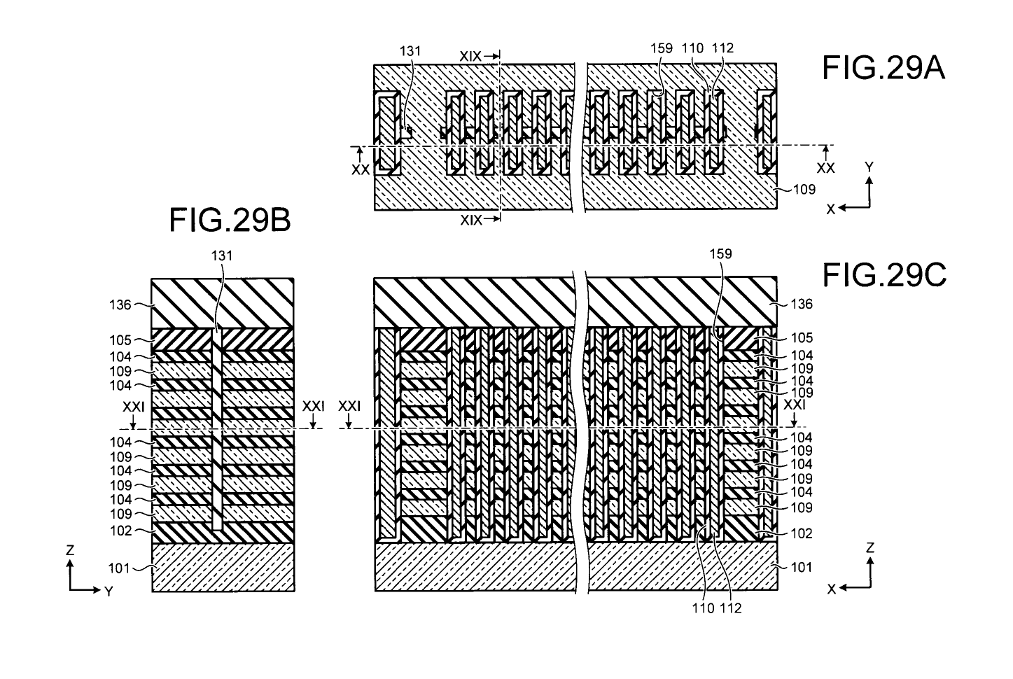

Next, as illustrated in FIGS. 29A to 29C, by collectively processing the stacked films, which includes the gap-fill dielectric film 131, the hard mask film 105, the spacer film 104, and the floating gate electrode film 109 in the forming region of the memory cell MC, using a lithography technique and an RIE technique, a control gate electrode film-forming trench 159, which functions as a mold of the control gate electrode film, is formed to expose the bottom surface of the ILD film 102. For example, the control gate electrode film-forming trench 159 having the width of 45 nm in the X direction may be formed at a pitch 60 nm in the X direction.

Next, an IPD film 110 is formed over the entire surface of the semiconductor substrate 101. The IPD film 110 is formed to conformally cover the inside of the control gate electrode film-forming trench 159. For example, a hafnia film having a thickness of 11 nm may be used as the IPD film 110.

Then, a conductive film 112 functioning as part of the control gate electrode film is filled in the control gate electrode film-forming trench 159. For example, a P-doped amorphous silicon film having a thickness of 30 nm may be used as the conductive film 112. Thereafter, a portion of the conductive film 112 and a portion of the IPD film 110, which are formed in a region other than the control gate electrode film-forming trench 159, are removed using a CMP technique.

Then, a hard mask film 136 for processing the channel semiconductor film 103 is formed over the entire surface of the semiconductor substrate 101. For example, a silicon nitride film having a thickness of 150 nm may be used as the hard mask film 136.

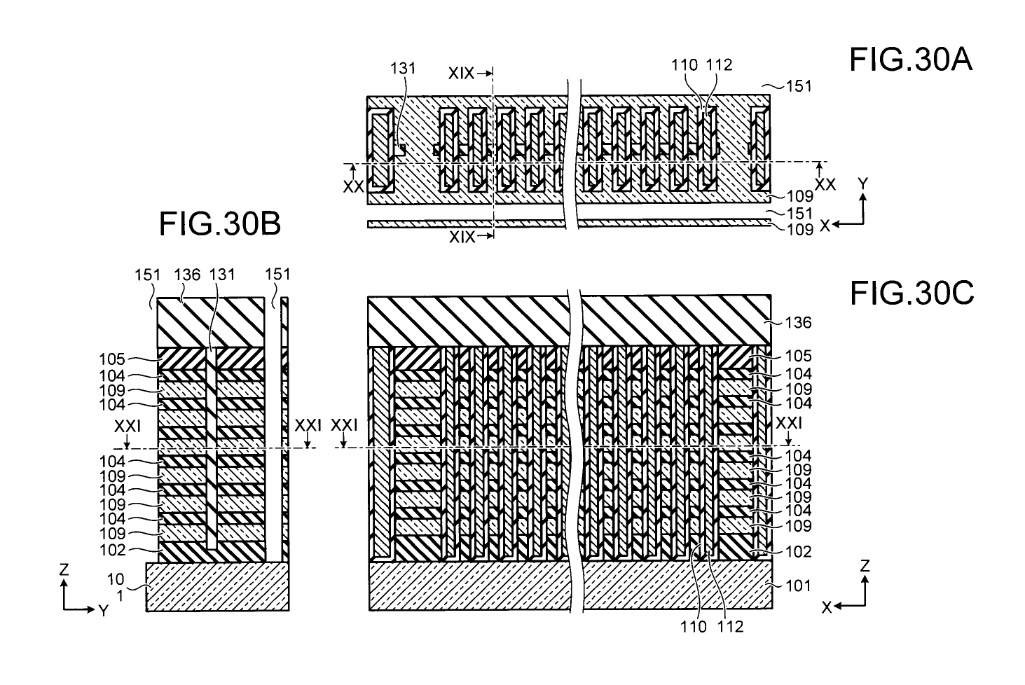

Thereafter, as illustrated in FIGS. 30A to 30C, by collectively processing the stacked films, which includes the hard mask films 136 and 105, the spacer film 104, and the floating gate electrode film 109, using a lithography technique and an RIE technique, a trench 151, which extends in the X direction to expose a part of the ILD film 102, is formed at a predetermined pitch in the Y direction. The trench 151 corresponds to one which divides an area for forming the NAND string group NSG in FIGS. 14 and 15A to 15C, and the pitch thereof in the Y direction is set to a dimension of the NAND string group NSG in the Y direction. For example, the trench 151 having a width of 40 nm may be formed at a pitch 240 nm in the Y direction.

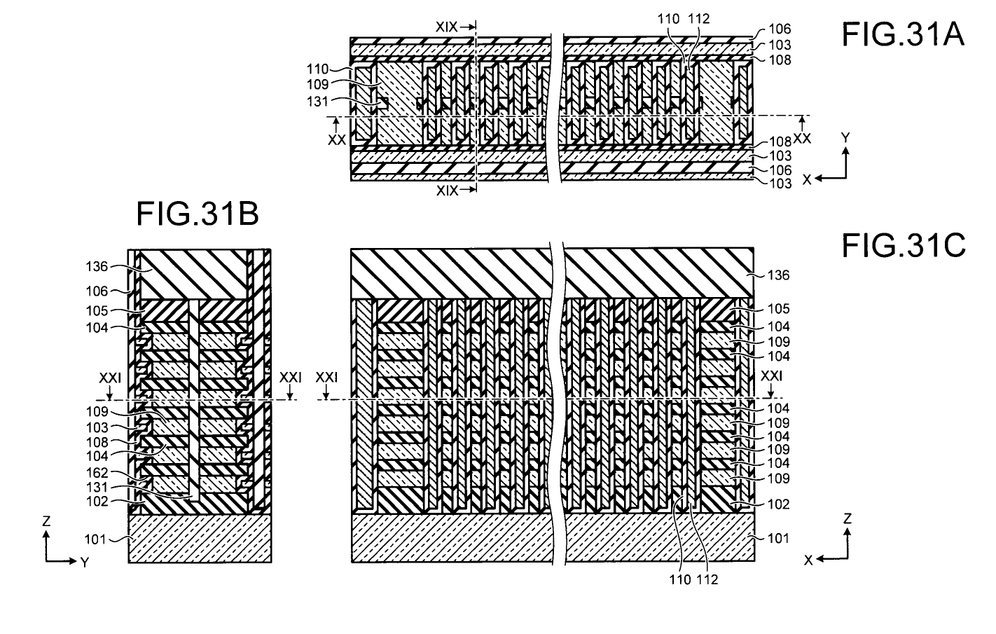

Thereafter, as illustrated in FIGS. 31A to 31C, a space 162 is formed by forming a recess in the floating gate electrode film 109 by a predetermined amount in the Y direction by using an etching technique. For example, a wet etching technique using choline, a CDE technique, a dry etching technique using chlorine gas, or the like may be used as the etching technique. The floating gate electrode film 109 is preferably etched so as to form a recess in the Y direction by an amount by which the floating gate electrode film 109 is divided for each memory cell MC between the control gate electrode film-forming trenches 159 arranged in the X direction. For example, the recess amount of the floating gate electrode film 109 may be set to 40 nm.

Next, a tunnel dielectric film 108 is formed on a side surface of the floating gate electrode film 109 inside the space 162. For example, a silicon oxide film having a thickness of 7 nm formed by an atomic layer deposition (ALD) technique may be used as the tunnel dielectric film 108.

Then, a channel semiconductor film 103 is formed over the entire surface of the semiconductor substrate 101. For example, an amorphous silicon film having a thickness of 10 nm may be used as the channel semiconductor film 103. Thereafter, the channel semiconductor film 103 is etched by a dry etching technique so as to have a recess, and hence the channel semiconductor film 103 remains only in the space 162 formed by etching the floating gate electrode film 109 to have a recess. For example, chlorine gas may be used as etching gas.

As described above, after the IPD film 110 and the conductive film 112 functioning as the control gate electrode film are formed to be filled in the control gate electrode film-forming trench 159, the trench 151 is formed at a position close to the end portion of the conductive film 112 in the Y direction, and the tunnel dielectric film 108 and the channel semiconductor film 103 are formed in the space 162 formed by forming a recess in the floating gate electrode film 109. Thus, provided is a structure in which the tunnel dielectric film 108 and the IPD film 110 remain between the control gate electrode film (the conductive film 112) and the channel semiconductor film 103. Further, after the tunnel dielectric film 108 is formed in the space 162, the channel semiconductor film 103 is formed. Thus, the width of the floating gate electrode film 109 is wider than the width of the channel semiconductor film 103.

Thereafter, the gap-fill dielectric film 106 is formed to be filled in the trench 151, and a planarization process is performed by a CMP technique until the mask film 136 is exposed in a region other than the forming position of the trench 151. For example, a silicon oxide film formed by a CVD technique may be used as the gap-fill dielectric film 106.

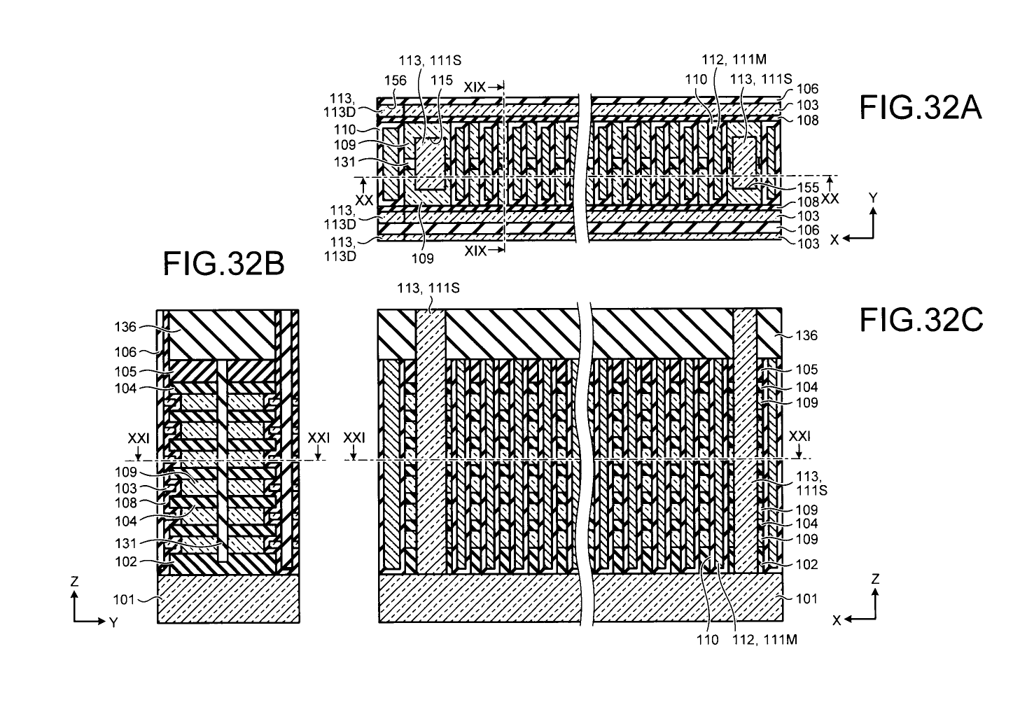

Next, as illustrated in FIGS. 32A to 32C, a selection gate electrode film-forming trench 155 and a drain region connection contact forming trench 156 are formed using a lithography technique and an RIE technique. The selection gate electrode film-forming trench 155 is formed by collectively processing the stacked films such that the stacked films including the hard mask films 136 and 105, the spacer film 104, the floating gate electrode films 109, and the interlayer dielectric film 102 of a pair of NAND string stacks NSS, which face each other, in the forming regions of the selection transistors ST can be partially removed and so the floating gate electrode film 109 of the lowest layer is exposed. The drain region connection contact forming trench 156 is formed by collectively processing the stacked films such that the drain region of each NAND string stack NSS can be partially removed and the floating gate electrode film 109 of the lowest layer is exposed.

Thereafter, a conductive film 113 is formed to be filled in the selection gate electrode film-forming trench 155 and the inside of the drain region connection contact forming trench 156. Then, a planarization process is performed using a CMP technique so that the conductive film 113 remains only in the selection gate electrode film forming trench 155 and the drain region connection contact forming trench 156. For example, a P-doped amorphous silicon film having a thickness of 80 nm may be used as the conductive film 113. As a result, in the forming region of the selection transistor ST, made is a common connection between the floating gate electrode films 109 of the memory cells MC facing each other through the gap-fill dielectric film 131 therebetween. The drain region connection contact 113D is formed in the drain region connection contact forming trench 156.

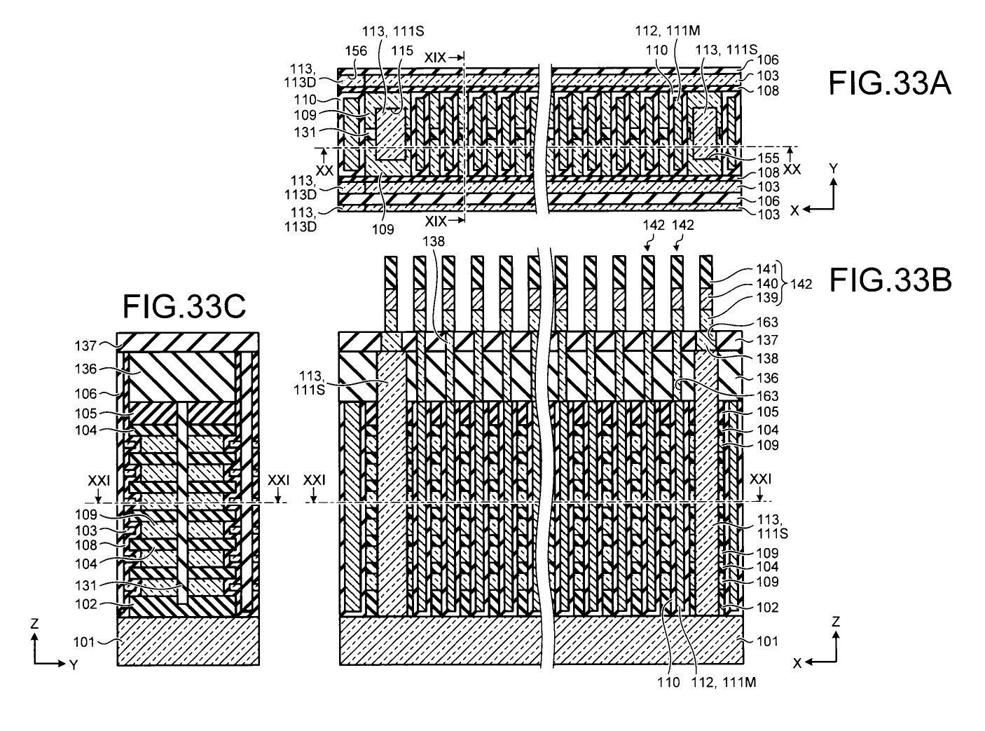

Next, as illustrated in FIGS. 33A to 33C, an ILD film 137 is formed over the entire surface of the semiconductor substrate 101. For example, a silicon oxide film having a thickness of 50 nm may be used as the ILD film 137. Thereafter, a contact hole 163 is formed using a lithography technique and an RIE technique to expose the control gate electrode film 111M and the selection gate electrode film 111S.

Thereafter, conductive films 139 and 140 and a hard mask film 141 are formed over the entire surface of the semiconductor substrate 101. For example, a P-doped amorphous silicon film having a thickness of 50 nm formed by a CVD technique may be used as the conductive film 139, and a TaN/W stacked film having a thickness 50 nm may be used as the conductive film 140. Further, a silicon nitride film having a thickness of 80 nm may be used as the hard mask film 141. The conductive film 139 is formed to be filled in the contact hole 163 and functions a contact plug 138.

Next, by processing the hard mask film 141 and the conductive films 139 and 140 using a lithography technique and an RIE technique, a control gate electrode pattern 142 having a predetermined half pitch is formed on a region in which the contact plug 138 is formed. Here, formed is the control gate electrode pattern 142 having a half pitch of 30 nm in the X direction. The control gate electrode film 111M is configured with the conductive film 112, the contact plug 138, the conductive films 139, and 140. The selection gate electrode film 1115 is configured with the floating gate electrode film 109, the conductive film 113, the contact plug 138, and the conductive films 139 and 140.

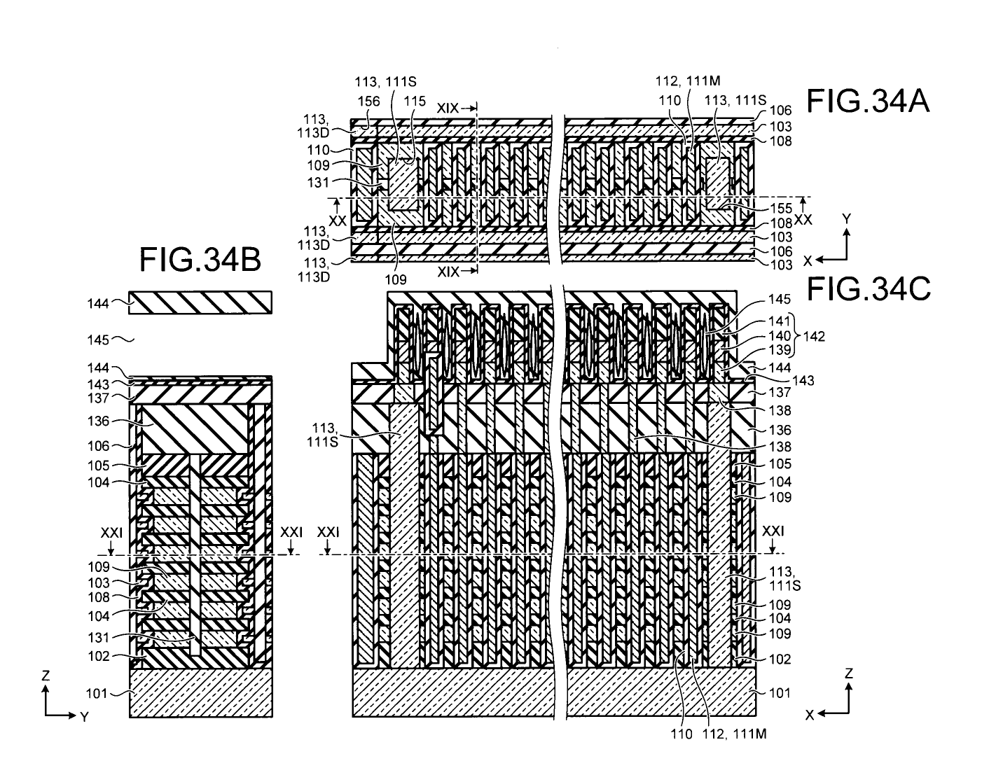

Next, as illustrated in FIGS. 34A to 34C, a side wall film 143 of the control gate electrode pattern 142 is formed. For example, a silicon oxide film having a thickness of 5 nm formed by a low temperature ALD technique may be used as the side wall film 143. Subsequently, a dielectric film 144 is formed over the entire surface of the semiconductor substrate 101 using a film forming technique having poor step coverage. For example, a tetraethoxysilane (TEOS) film having a thickness of 100 nm formed by a plasma enhanced CVD (PECVD) may be used as the dielectric film 144. As a result, an air gap 145 is formed between the control gate electrode patterns 142 adjacent to each other in the X direction. As described above, since the air gap 145 is formed between the control gate electrode patterns 142, parasitic capacitance between the control gate electrode films 111M can be reduced.

Then, an ILD film is formed, and thereafter a contact plug and a wiring are formed. However, the contact plug and the wiring may be formed using a known technique, and thus a detailed description thereof will be omitted. Through the above process, the non-volatile semiconductor memory device according to the fifth embodiment is obtained.

In the fifth embodiment, the floating gate electrode film 109 into which a dopant is doped at a high concentration is initially stacked via the spacer film 104, and then the control gate electrode film-forming trench 159 is formed and filled with the IPD film 110 and the control gate electrode film 111M. Thereafter, the trench 151 is formed at the position close to the end portion of the IPD film 110 in the Y direction, and the space 162 formed by forming a recess in the floating gate electrode film 109 is filled with the tunnel dielectric film 108 and the channel semiconductor film 103. As a result, the IPD film 110 and the tunnel dielectric film 108 can be formed between the channel semiconductor film 103 and the control gate electrode film 111M. Accordingly, there are effects capable of avoiding a situation in which only the IPD film 110 is present between the control gate electrode film 111M and the channel semiconductor film 103 and preventing a leak from the channel semiconductor film 103 to the control gate electrode film 111M.

Further, since the width of the floating gate electrode film 109 is easily increased to be wider than the width the channel semiconductor film 103, there are effects capable of increasing controllability of a channel and easily attaining a higher coupling ratio.

### Sixth Embodiment

In the manufacturing methods described in the first to fifth embodiments, the memory cell MC is a thin film transistor (TFT) formed on the channel semiconductor film 103 made of polysilicon (amorphous silicon is used when a film is formed, however, amorphous silicon is finally converted to polycrystalline silicon by crystallization). However, the TFT has disadvantages in that it is difficult to achieve high mobility due to influence of a grain boundary, and cell characteristics such as a threshold voltage distribution easily vary due to the influence of the grain boundary. In this regard, a sixth embodiment will be described in connection with a method of manufacturing a non-volatile semiconductor memory device having the channel semiconductor film 103 made of single crystal.

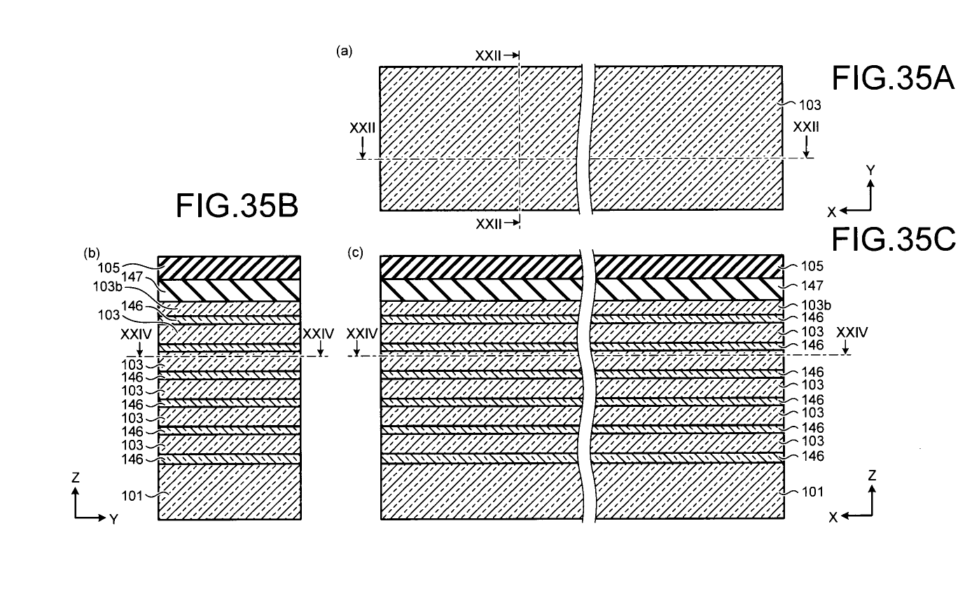

FIGS. 35A to 41C are cross-sectional views schematically illustrating an example of a process of a method of manufacturing a non-volatile semiconductor memory device according to a sixth embodiment. In these drawings, FIGS. 35A to 41A are cross-sectional views when it is viewed in a direction parallel to a substrate surface at a forming position of a floating gate electrode film, FIGS. 35B to 41B are cross-sectional views taken along line XXII-XXII of FIGS. 35A to 41A, and FIGS. 35C to 41C are cross-sectional views taken along line XXIII-XXIII of FIGS. 35A to 41A. FIGS. 35A to 41A correspond to cross-sectional views taken along line XXIV-XXIV of FIGS. 35B to 41B and FIGS. 35C and 41C.

In the following, described is an example of manufacturing a non-volatile semiconductor memory device having a structure in which six layers, each including a channel semiconductor film 103 and a sacrificial film 146, are stacked at a pitch of 60 nm in parallel to a semiconductor substrate 101, a half pitch in the Y direction is 62 nm, and a half pitch in the X direction is 25 nm.

First, as illustrated in FIGS. 35A to 35C, a peripheral circuit (not illustrated) of the non-volatile semiconductor memory device is formed on the semiconductor substrate 101, and the region of the semiconductor substrate 101 in which the memory cell MC is to be formed is exposed. For example, a silicon substrate may be used as the semiconductor substrate 101.

Next, formed are a plurality of layers in which the sacrificial film 146 of single crystal and the channel semiconductor film 103 of single crystal are alternately stacked over the entire surface of the semiconductor substrate 101. Here, six layers of the sacrificial films 146 having the same thickness and five layers of the channel semiconductor films 103 having the same thickness are alternately formed. Thereafter, a channel semiconductor film 103b having a thickness larger than that of the channel semiconductor films 103 is formed on the sacrificial film 146 of the top layer. The sacrificial films 146 and the channel semiconductor films 103 and 103b of single crystal may be formed using a selective epitaxial growth technique or a blanket epitaxial growth technique. For example, a single crystalline SiGe film having a thickness of 20 nm may be used as the sacrificial film 146. For example, a single crystalline silicon film having a thickness of 40 nm may be used as the channel semiconductor film 103. For example, a single crystalline silicon film having a thickness of 50 nm may be used as the channel semiconductor film 103b.

Thereafter, the upper portion of the channel semiconductor film 103b of the top layer is oxidized to form a spacer film 147. For example, a silicon thermal oxide film having a thickness of 40 nm, formed by oxidizing the upper portion of the channel semiconductor film 103b by 20 nm, may be used as the spacer film 147.

Then, a hard mask film 105 is formed on the spacer film 147. For example, a silicon nitride film having a thickness of 50 nm may be used as the hard mask film 105. Further, the hard mask film 105 may be formed using a film made of SiCN, SiBN, alumina, titania, zirconia, or the like besides the silicon nitride film. Moreover, it is preferable that the hard mask film 105 can be easily etched to form a recess that acts as a mold of floating gates.

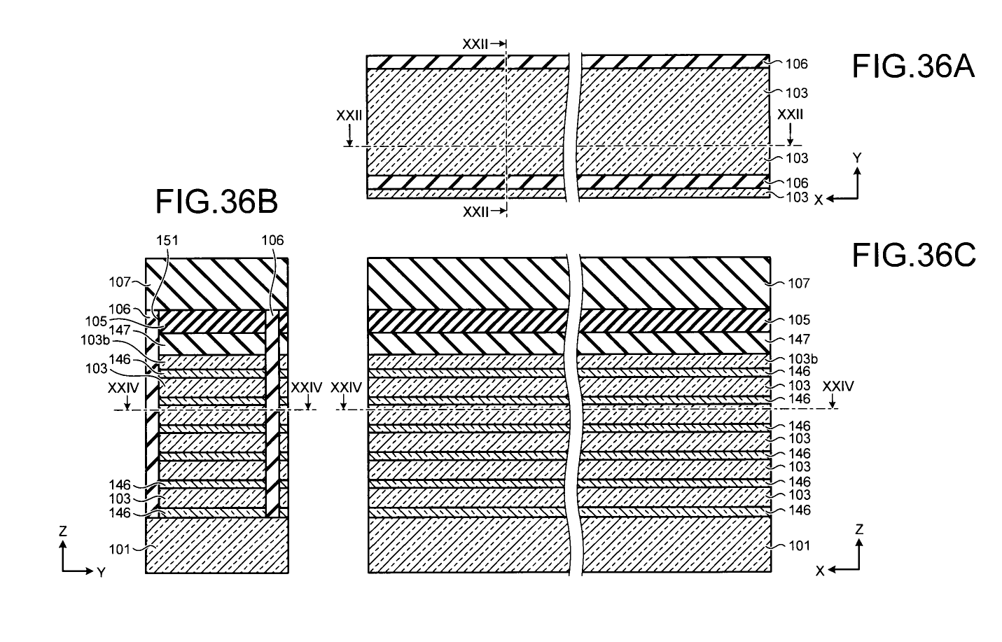

Next, as illustrated in FIGS. 36A to 36C, by collectively processing the stacked films, which includes the hard mask film 105, the spacer film 147, the channel semiconductor films 103 and 103b, and the sacrificial films 146, using a lithography technique and an RIE technique, a trench 151, which extends in the X direction to expose the semiconductor substrate 101, is formed at a predetermined pitch in the Y direction. For example, the width of the trench 151 may be set to 25 nm, and the pitch may be set to 248 nm. The trench 151 corresponds to one which divides the stacked films in association with an area for forming the NAND string group NSG facing the memory cell MC, and isolates the channel semiconductor films 103 of the memory cells MC, adjacent to each other, in the NAND string groups NSG adjacent to each other in the Y direction, in FIG. 1 and FIGS. 2A to 2C.

Thereafter, a gap-fill dielectric film 106 is formed in the trench 151. The upper surface of the gap-fill dielectric film 106 is planarized using a CMP technique, and so the hard mask film 105 is exposed in a region other than the position at which the trench 151 is formed. For example, a silicon oxide film formed by a CVD technique may be used as the gap-fill dielectric film 106. Then, a hard mask film 107 is formed over the entire surface of the semiconductor substrate 101. For example, a silicon nitride film having a thickness of 100 nm may be used as the hard mask film 107.

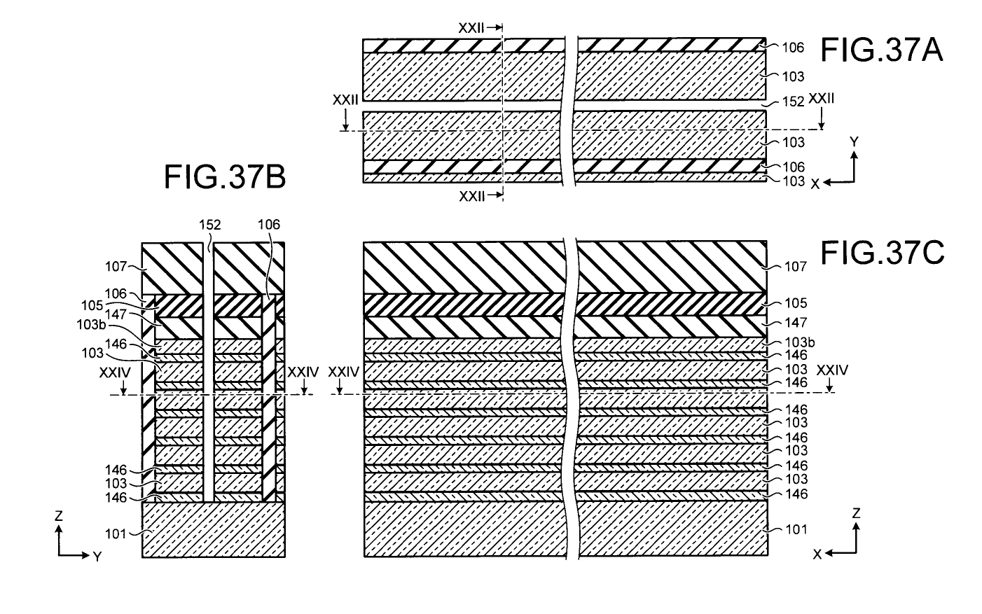

Next, as illustrated in FIGS. 37A to 37C, by collectively processing the stacked films, which includes the hard mask films 107 and 105, the spacer film 147, the channel semiconductor films 103 and 103b, and the sacrificial films 146, using a lithography technique and an RIE technique, a trench 152, which extends in the X direction to expose the semiconductor substrate 101, is formed at a predetermined pitch in the Y direction. For example, the width of the trench 152 may be set to 25 nm. The trench 152 corresponds to one which divides an area for forming the NAND string stack NSS in FIG. 1 and FIGS. 2A to 2C.

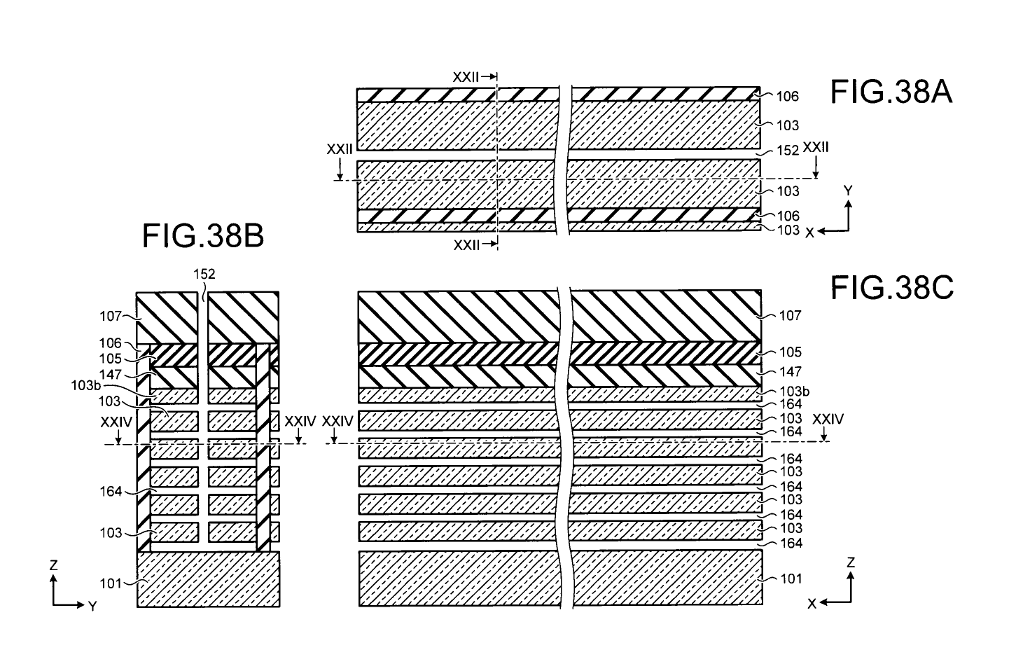

Thereafter, as illustrated in FIGS. 38A to 38C, a space 164 is formed by selectively removing the sacrificial film 146 by using an etching technique. For example, a wet etching technique using a mixed solution of hydrofluoric acid/nitric acid/pure water=1:90:60, a CDE technique, a dry etching technique using chlorine gas, or the like may be used as the etching technique. As a result, provided is a structure in which the channel semiconductor films 103 and 103b are supported by the gap-fill dielectric film 106.

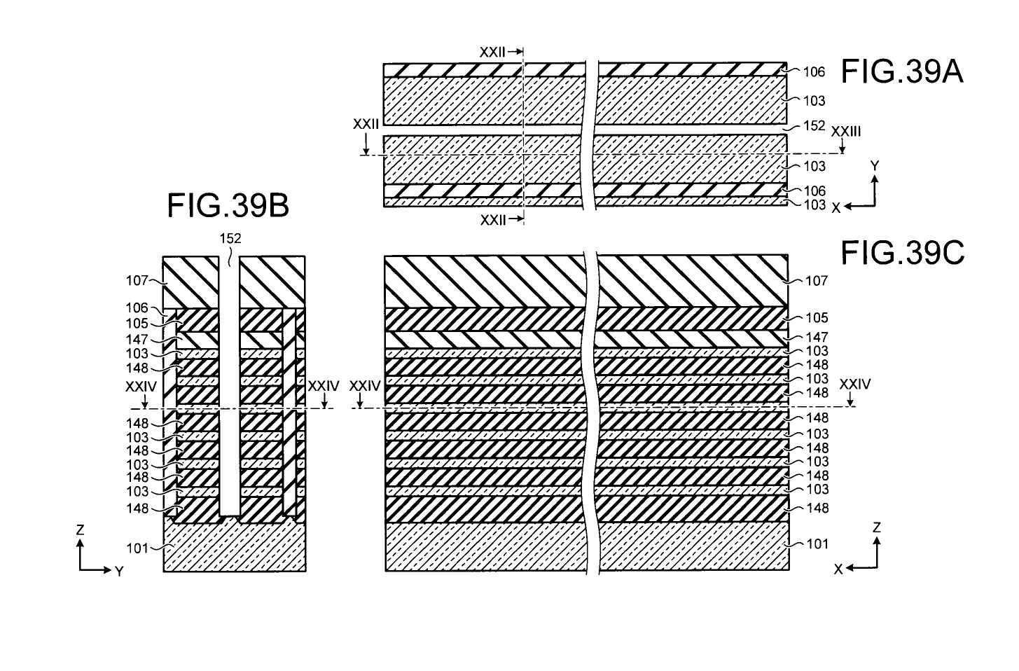

Next, as illustrated in FIGS. 39A to 39C, the entire surfaces of the channel semiconductor films 103 and 103b exposed by removing the sacrificial film 146 are oxidized to form an oxide film 148, and so the space 164 is completely filled with the oxide film 148. For example, as the oxide film, a silicon thermal oxide film of about 20 nm may be formed by oxidizing one side (both upper and lower surfaces) of the channel semiconductor films 103 and 103b by 10 nm by a steam oxidation process. As one side is oxidized by 10 nm, the thickness of the channel semiconductor films 103 and 103b is about 20 nm (hereinafter, the channel semiconductor film of the top layer is also designated with symbol 103). Thus, provided is a structure in which the channel semiconductor films 103 adjacent to each other in the Z direction are isolated by the oxide film 148. Thereafter, the oxide film 148 formed in the trench 152 is removed by 20 nm by an isotropic dry etching technique, and so an end portion of the channel semiconductor film 103 in the Y direction is exposed in the trench 152. Downflow radical generated by plasma of NF₃ and NH₃ may be used for the isotropic dry etching technique.

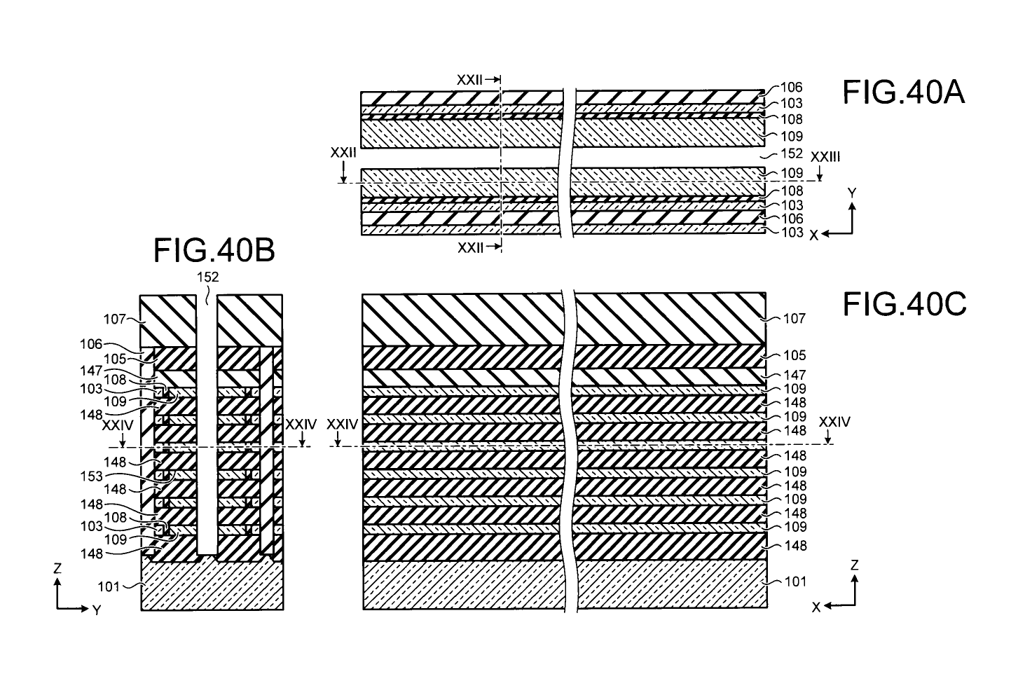

Next, as illustrated in FIGS. 40A to 40C, a space 153 is formed by forming a recess in the channel semiconductor film 103 by a predetermined amount in the Y direction by using an etching technique. For example, a wet etching technique using choline, a CDE technique, a dry etching technique using chlorine gas, or the like may be used as the etching technique. For example, the recess amount of the channel semiconductor film 103 may be set to 50 nm.

Next, a tunnel dielectric film 108 is formed on a side surface of the channel semiconductor film 103 inside the space 153. For example, the tunnel dielectric film 108 may be formed using a technique such as a thermal oxidation technique, a thermal nitridation technique, or a plasma nitridation technique. Then, a floating gate electrode film 109 is formed over the entire surface of the semiconductor substrate 101. For example, a P-doped amorphous silicon film having a thickness of 15 nm may be used as the floating gate electrode film 109. Thereafter, the floating gate electrode film 109 is continuously etched to form a recess by a dry etching technique so that the floating gate electrode film 109 remains only in the space 153. For example, chlorine gas may be used as etching gas. As a result, formed is a structure in which the floating gate electrode film 109 is stacked above the single crystalline silicon via the tunnel dielectric film 108, similarly to the typical NAND flash type memory of the planar floating gate type structure.

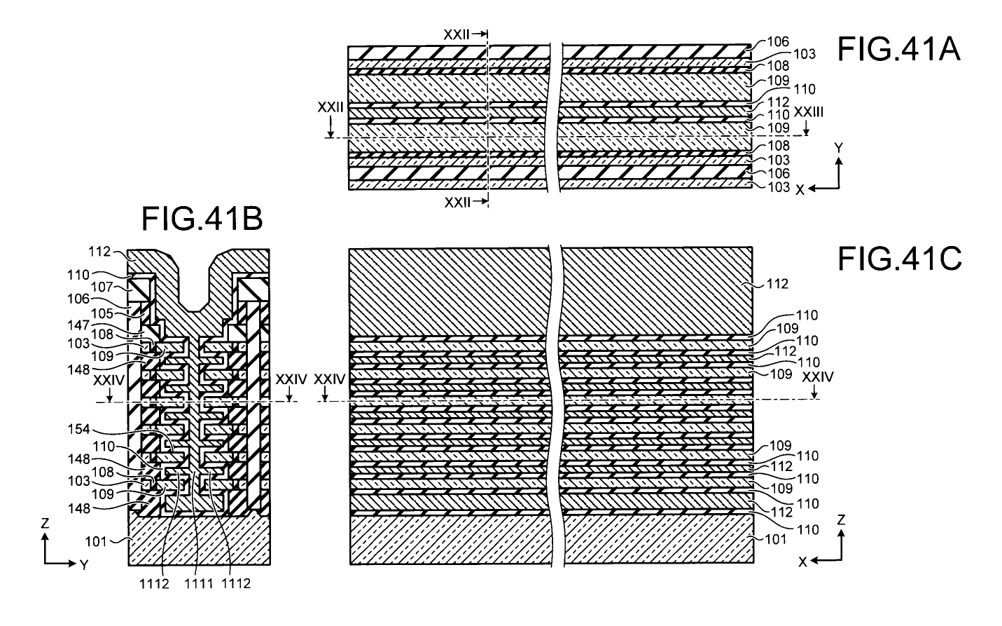

Next, as illustrated in FIGS. 41A to 41C, by forming a recess in the oxide film 148 from the end portion of the floating gate electrode film 109 configuring the side wall of the trench 152 in the Y direction by a predetermined amount using an isotropic etching technique, a space 154 is formed which is to be filled with the control gate electrode film 111M. For example, a wet etching technique, a dry etching technique using HF/NH₃ gas, or a dry etching by down flow radical generated by plasma of NF₃ and NH₃ may be used as the isotropic etching. For example, the recess amount of the oxide film 148 may be set to 40 nm.

Then, the hard mask films 107 and 105 are etched to form a recess starting from the end portion of the floating gate electrode film 109 by a predetermined amount by using an isotropic etching technique. For example, a wet etching technique using a hot phosphoric acid may be used as the isotropic etching technique. For example, the recess amount of the hard mask films 107 and 105 may be set to 50 nm.

Thereafter, an IPD film 110 is formed over the entire surface of the semiconductor substrate 101. The IPD film 110 is formed to conformally cover the inside of the space 154. A SiO—SiN—SiO (ONO) film having a thickness of 9 nm may be used as the IPD film 110.

Further, a conductive film 112 functioning as part of the control gate electrode film 111M is formed over the entire surface of the semiconductor substrate 101. Here, the conductive film 112 is formed to be filled in the trench 152 and the space 154 formed in the trench 152. For example, a P-doped polysilicon film having a thickness of 50 nm may be used as the conductive film 112. The conductive film 112 functions as part of the control gate electrode film 111M and part of the selection gate electrode film 111S, and has a structure in which the electrode forming section 1112 is formed in the space 154, and the electrode forming sections 1112 of the control gate electrode films 111M, which are stacked in the Z direction via the IPD film 110, are connected to each other, between the floating gate electrode films 109, by the common connecting section 1111 extending in the Z direction. As a result, formed is a structure in which the tunnel dielectric film 108, the floating gate electrode film 109, the IPD film 110, and the conductive film 112 (the control gate electrode film 111M) are stacked on the channel semiconductor film 103.

Thereafter, performed is a process of forming the selection gate electrode film-forming trench 155 and the drain region connection contact forming trench 156 illustrated in FIGS. 9A to 9C according to the first embodiment. However, the process is the same as the process described in the first embodiment, and thus the redundant description will not be repeated.

In the sixth embodiment, formed are a plurality of layers in which the sacrificial films 146 of single crystal and the channel semiconductor films 103 and 103b of single crystal, which extend in the X direction in parallel to the substrate surface, are alternately stacked in the Z direction. The trench 152 extending in the X direction is formed. Thereafter, the oxide film 148 is formed by oxidizing the channel semiconductor films 103 and 103b so as to be filled in the space 164 formed by removing the sacrificial film 146. Next, the space 153 is formed by forming a recess in the channel semiconductor films 103 and 103b by a predetermined amount, and the tunnel dielectric film 108 is formed in the space 153. Thereafter, the space 153 is filled with the floating gate electrode film 109. Thereafter, the IPD film 110 and the control gate electrode film 111M are formed by forming a recess in the oxide film 148 by a predetermined amount. As a result, the channel semiconductor film 103 can be formed of a single crystalline semiconductor film having no grain boundary, and it is possible to form a non-volatile semiconductor memory device capable of high speed operation and suppressing a variation in a threshold voltage distribution. Further, since the channel semiconductor film 103 is stacked in parallel to the semiconductor substrate 101, there is an effect capable of performing single crystallization of the channel semiconductor film 103 using crystallization information of the semiconductor substrate 101.

The above description has been made in connection with the example of manufacturing the non-volatile semiconductor memory devices according to the first, third, and fourth embodiments. However, the above described manufacturing method can be similarly applied to the non-volatile semiconductor memory devices according to the second and fifth embodiment.

### Seventh Embodiment

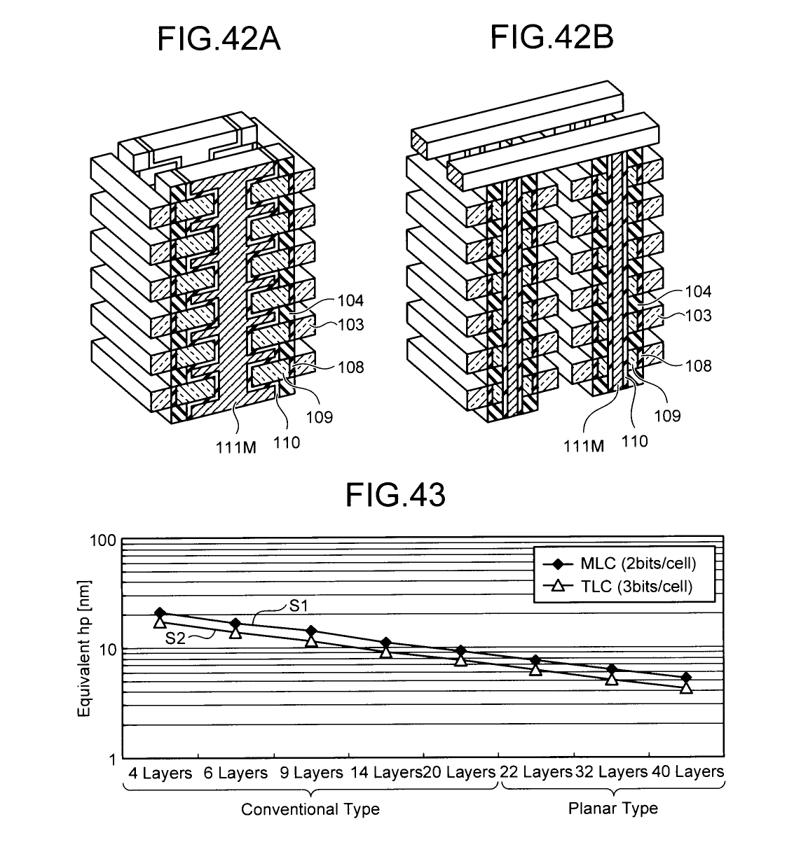

A seventh embodiment will be described in connection with a scaling scenario of the non-volatile semiconductor memory devices according to the above embodiments. FIGS. 42A and 42B are perspective views schematically illustrating an example of a structure of a non-volatile semiconductor memory device according to an embodiment. FIG. 42A illustrates the structure of the non-volatile semiconductor memory device according to the first embodiment, and FIG. 42B illustrates a modified embodiment of FIG. 42A.

The non-volatile semiconductor memory device illustrated in FIG. 42A has a structure in which the channel semiconductor films 103 on which the floating gate electrode film 109 is formed via the tunnel dielectric film 108 are stacked on one side in a height direction, and the control gate electrode film 111M is formed on three surfaces (upper, lower, and side surfaces) of the floating gate electrode film 109 via the IPD film 110, as already described above.

However, the non-volatile semiconductor memory device illustrated in FIG. 42B has a structure in which the channel semiconductor films 103 on which the floating gate electrode film 109 is formed via the tunnel dielectric film 108 are stacked on one side in a height direction, and the control gate electrode film 111M is formed on only the side surface of the floating gate electrode film 109 via the IPD film 110. That is, the IPD film 110 is formed on only one surface (side surface) of the floating gate electrode film 109. It is because the control gate electrode film 111M does not enter between the floating gate electrode films 109. The other structure is the same as in the first embodiment, and thus the redundant description will not be repeated.

In the stacked volatile semiconductor memory devices according to the above embodiments, by increasing the number of stacked layers, the effective half pitch can be reduced. However, when the number of stacked layers is increased, the staked film thickness of the memory cell MC increases, processing difficulty increases, and the lead-out portion 180 of each channel semiconductor film 103 staked as described in the first embodiment increases in size. In this regard, in a stage in which the number of stacked layers is not so many, it is desirable to employ the structure in which the IPD film 110 is formed on the three surfaces of the floating gate electrode film 109, which is illustrated in FIG. 42A. The structure of FIG. 42A is almost the same structure as in the NAND flash type memory of floating gate type which is currently being produced in large quantities, and there is little problem about a memory operation or reliability assurance. However, both the number of stacked layers and the stacked film thickness are likely to increase.

Meanwhile, in a stage in which the number of stacked layers increases, it is desirable to employ the structure of using only one surface of the floating gate electrode film 109, which is illustrated in FIG. 42B. As a result, the projected area of the memory cell MC can be reduced, and the number of stacked layers and the stacked film thickness of the memory cell MC can be suppressed. However, in order to suppress the number of stacked layers and the stacked film thickness, required is an idea for employing a high-k material for the IPD film 110 or for employing a film structure for accumulating charges in the IPD film 110.

FIG. 43 is a diagram illustrating a scaling scenario of a non-volatile semiconductor memory device according to an embodiment. In FIG. 43, a horizontal axis represents the number of stacked layers of the memory cell MC, and a vertical axis represents an equivalent half pitch (nm) when the planar floating gate type structure is employed. A curved line S1 represents a scaling scenario of a half pitch corresponding to an MLC (2 bits/cell), and a curved line S2 represents a scaling scenario of a half pitch corresponding to a TLC (3 bits/cell).

It can be understood that when an MLC represented by the curved line S1 of FIG. 43 is used, if the present structure is introduced into the generation of about a 20 nm half-pitch and subsequent generations, five generations subsequent thereto can be scaled (down) by the conventional floating gate type structure of FIG. 42A, and three generations subsequent thereto can be further scaled by the structure of FIG. 42B. In addition, it can be understood that in the floating gate type structure, by employing a TLC which is relatively easily implemented, further scaling can be performed as represented by the curved line S2.

The above embodiments are examples, and the number of stacked layers of the non-volatile semiconductor memory device is not limited to the above examples. The number of stacked layers other than 4 layers or 6 layers may be used.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a non-volatile semiconductor memory device, comprising:
forming a stacked structure including a plurality of layers in which spacer films and channel semiconductor films are alternately stacked above a substrate;
forming a first trench extending in a first direction in the stacked structure;
forming a first space by forming a recess in the channel semiconductor films from the first trench in a second direction perpendicular to the first direction;
forming a tunnel dielectric film on the channel semiconductor films in the first space;
filling a floating gate electrode film in the first space, in which the tunnel dielectric film is formed; and
forming second trenches that divide the stacked structure at predetermined interval in the first direction so as to divide the floating gate electrode film between memory cells adjacent to each other in the first direction but so as not to divide the channel semiconductor films, wherein the stacked structure is divided at predetermined interval in the second direction so that the channel semiconductor films are divided between memory cells adjacent to each other in the second direction.

2. The method according to claim 1, further comprising:
forming a recess in the spacer films from the first trench in the second direction after the filling of the floating gate electrode film and before the forming of the second trenches;
forming an inter-electrode dielectric film on the floating gate electrode film in the first trench and on the recessed spacer films; and
filling a control gate electrode film in the first trench, in which the inter-electrode dielectric film is formed,
wherein the forming of the second trenches includes forming the second trenches so as not to divide the channel semiconductor films in the first direction but to divide the floating gate electrode film, the inter-electrode dielectric film, and the control gate electrode film in the first direction.

3. The method according to claim 1, further comprising:
filling a gap-fill dielectric film in the first trench after the filling of the floating gate electrode film and before the forming of the second trenches;
forming an inter-electrode dielectric film to conformally cover an inner surface of the second trenches after the forming of the second trenches; and
filling a control gate electrode film in the second trenches covered with the inter-electrode dielectric film.

4. The method according to claim 2, further comprising:
forming an oxide film by oxidizing a surface of the floating gate electrode film in the first trench, after the forming of the recess in the spacer films; and
removing the oxide film on the surface of the floating gate electrode film before the forming of the inter-electrode dielectric film.

5. The method according to claim 1, wherein the filling of the floating gate electrode film includes:
filling a first conductive film in the first space;
forming a recess in the first conductive film from the first trench in the second direction;
forming a second space around an end of the recess in the first conductive film in the second direction by isotropically etching the spacer films, and
filling a second conductive film in the second space to form the floating gate electrode film including the first conductive film and the second conductive film.

6. The method according to claim 1, further comprising:
forming a back gate electrode film on a side surface of the stacked structure divided in the second direction through a dielectric film therebetween.

7. The method according to claim 1, wherein
the forming of the first trench includes forming a mask film on the stacked structure and forming the first trench in the stacked structure so as to punch through the mask film, and
the method further including forming a recess extending in the second direction in the mask film so as to cover a region where the channel semiconductor films are to be formed but so as not to cover a region where the floating gate electrode film is to be formed with a top-down view after the filling of the floating gate electrode film.

8. The method according to claim 2, further comprising:
performing an oxidation process to oxidize a surface of the floating gate electrode film and a surface of the control gate electrode film after the forming of the second trenches.

9. The method according to claim 8, further comprising:
forming a side wall film in the second trenches.

10. The method according to claim 1, further comprising:
forming a selection gate electrode film-forming trenches that punch through the stacked structure, in a formation region of the floating gate electrode film, outside both ends of a memory row including a predetermined number of memory cells arranged in the first direction; and
filling a selection gate electrode film in the selection gate electrode film-forming trenches.

11. A method of manufacturing a non-volatile semiconductor memory device, comprising:
forming a stacked structure including a plurality of layers in which spacer films and floating gate electrode films are alternately stacked above a substrate;
forming trenches that function as a mold of a control gate electrode film in the stacked structure at predetermined interval in a first direction;
forming an inter-electrode dielectric film in the trenches to cover an inner surface of the mold;
filling a control gate electrode film in the trenches, in which the inter-electrode dielectric film is formed;
forming a different trench extending in the first direction in the stacked structure outside an end portion of the trenches in a second direction perpendicular to the first direction;
forming a space by forming a recess in the floating gate electrode films such that the recess extends from the different trench in the second direction by a predetermined amount;
forming a tunnel dielectric film on the floating gate electrode films in the space; and
filling a channel semiconductor film in the space, in which the tunnel dielectric film is formed.

12. The method according to claim 11, further comprising:
forming a selection gate electrode film-forming trenches that punch through the stacked structure, in a formation region of the floating gate electrode films, outside both ends of a memory row including a predetermined number of memory cells arranged in the first direction; and
filling a selection gate electrode film in the selection gate electrode film-forming trenches.

13. A non-volatile semiconductor memory device, comprising:
a plurality of sheet shaped channel semiconductor films that extend in a first direction and are stacked in a height direction above a substrate, through a dielectric film between the plurality sheet shaped channel semiconductor films and the substrate;
memory cells arranged at predetermined interval in the first direction and each including a floating gate electrode formed on a tunnel dielectric film over only one side surface of one of the channel semiconductor films in a second direction perpendicular to the first direction, and a control gate electrode arranged to face the floating gate electrode through an inter-electrode dielectric film therebetween, the arranged memory cells being stacked in the height direction,
wherein the control gate electrode is formed to extend in the height direction so as to be shared between the memory cells stacked in the height direction.

14. The non-volatile semiconductor memory device according to claim 13,
wherein the control gate electrode includes a common connecting section that extends in the height direction, and electrode forming sections that protrude from the common connecting section in the second direction and are arranged above and below the floating gate electrode.

15. The non-volatile semiconductor memory device according to claim 13,
wherein the control gate electrode is arranged, on only a side surface of the floating gate electrode in the second direction, through the inter-electrode dielectric film interposed, and is mutually connected with those of the memory cells stacked in the height direction.

16. The non-volatile semiconductor memory device according to claim 13, further comprising:
a back gate electrode film formed, on a surface opposite to a memory-forming surface of the channel semiconductor films, through a dielectric film therebetween.

17. The non-volatile semiconductor memory device according to claim 13,
wherein the floating gate electrode thickness is reduced in the height direction between the tunnel dielectric film and an end portion in the second direction of the floating gate electrode.

18. The non-volatile semiconductor memory device according to claim 13,
wherein the floating gate electrode thickness is increased in the height direction between the tunnel dielectric film and an end portion in the second direction of the floating gate electrode.

19. The non-volatile semiconductor memory device according to claim 13,
wherein the channel semiconductor films are formed of a single crystalline semiconductor films.

20. The non-volatile semiconductor memory device according to claim 13,
wherein the control gate electrode is arranged on both side surfaces of the floating gate electrode in the first direction through the inter-electrode dielectric film.
